(19) United States
(12) Patent Application Publication
(10) Pub. No.: US 2025/0221192 A1
(43) Pub. Date: Jul. 3, 2025

(54) DISPLAY APPARATUS

(71) Applicant: LG Display Co., Ltd., Seoul (KR)

(72) Inventors: DongHun JUNG, Paju-si (KR); Uisu SIN, Paju-si (KR)

(73) Assignee: LG Display Co., Ltd., Seoul (KR)

(21) Appl. No.: 18/768,906

(22) Filed: Jul. 10, 2024

(30) Foreign Application Priority Data
Dec. 29, 2023 (KR) 10-2023-0197120

(51) Int. Cl. H10K 59/131

(52) U.S. Cl. CPC H10K 59/131

(57) ABSTRACT

Discussed is a display apparatus including a substrate including a display area having a plurality of subpixels and a non-display area adjacent to the display area, a plurality of data lines extending in a first direction in the display area, a plurality of vertical data link lines extending in the first direction in the display area, a plurality of horizontal data link lines extending in a second direction in the display area, a power supply line disposed in the non-display area, a plurality of vertical power distribution lines electrically connected to the power supply line and extending in the first direction in the display area, a plurality of horizontal power link lines extending in the second direction in the display area, and a plurality of vertical power link lines extending in the first direction in the display area.

### CROSS-REFERENCE TO RELATED APPLICATION

This application claims priority to Republic of Korea Patent Application No. 10-2023-0197120, filed on Dec. 29, 2023 in the Korean Intellectual Property Office, the entire contents of which is hereby expressly incorporated by reference into the present application.

### BACKGROUND

### Technical Field

The present disclosure relates to a display apparatus with a reduced bezel area.

### Discussion of the Related Art

A display apparatus can include a display area (which can be also referred to as an active area) configured to display an image to be displayed, as well as a non-display area (which can also referred to as a non-active area or a bezel area) where an image is not displayed. The display area can include pixels that can collectively generate an image. In order for the display apparatus to perform various functionalities such as displaying the image, sensing a touch event when a touch electrodes are also used, and the like, various structures, circuits, lines, and the like can be disposed in the non-display area of the display apparatus and away from the display area to ensure the display apparatus can have a maximum amount of area to display the image.

### SUMMARY OF THE DISCLOSURE

Due to such elements located in the non-display area, it is not easy to reduce a bezel of a display panel. In particular, since link lines for delivering data signals to data lines are disposed in the non-display area of the display panel, challenges can arise in reducing the bezel of the display panel. To address these issues, one or more aspects of the present disclosure can provide a display apparatus with a data link structure capable of reducing the bezel.

One or more aspects of the present disclosure can provide a display apparatus with a power line structure capable of improving the performance of transmitting a common driving voltage.

One or more aspects of the present disclosure can provide a display apparatus with a power line structure capable of helping to improve image quality.

One or more aspects of the present disclosure can provide a display apparatus with a power line structure suitable for a data link structure capable of reducing the bezel of a display panel.

According to aspects of the present disclosure, a display apparatus can include a substrate including a display area having a plurality of subpixels and a non-display area adjacent to the display area.

In one or more aspects, the display apparatus can include a plurality of data lines extending in a first direction in the display area, a plurality of vertical data link lines extending in the first direction in the display area, and a plurality of horizontal data link lines extending in a second direction in the display area.

In one or more aspects, the display apparatus can include a power supply line disposed in the non-display area, a plurality of vertical power distribution lines electrically connected to the power supply line and extending in the first direction in the display area, a plurality of horizontal power link lines extending in the second direction in the display area, and a plurality of vertical power link lines extending in the first direction in the display area.

According to aspects of the present disclosure, a display apparatus can include a substrate including a display area having a plurality of subpixels and a non-display area adjacent to the display area, a plurality of vertical data link lines extending in a first direction in the display area, a plurality of horizontal data link lines extending in a second direction in the display area, a power supply line disposed in the non-display area, at least one power distribution line, and a plurality of power link lines disposed in the display area and electrically connected to the at least one power distribution line.

According to one or more aspects of the present disclosure, a display apparatus can be provided that has a data link structure capable of reducing the bezel of a display panel.

According to one or more aspects of the present disclosure, a display apparatus can be provided that has a power line structure capable of improving the performance of transmitting a common driving voltage.

According to one or more aspects of the present disclosure, a display apparatus can be provided that has a power line structure capable of helping to improve image quality.

According to one or more aspects of the present disclosure, a display apparatus can be provided that has a power line structure suitable for a data link structure capable of reducing the bezel area of a display panel.

According to one or more aspects of the present disclosure, a display apparatus and a display panel can be provided that are capable of reducing the bezel of the display panel by applying an improved data link structure, and are configured to have a reduced weight.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure.

FIG. 1 illustrates a system configuration of a display apparatus according to aspects of the present disclosure.

FIG. 2 illustrates a display panel according to aspects of the present disclosure.

FIG. 3 is a cross-sectional view of the display panel according to aspects of the present disclosure.

FIG. 4 illustrates a substrate of the display panel according to aspects of the present disclosure.

FIG. 5 is a plan view of the display panel according to aspects of the present disclosure and illustrates a data link structure configured in the display panel.

FIG. 6 is another plan view of the display panel according to aspects of the present disclosure and illustrates a data link structure capable of reducing the bezel of the display panel.

FIG. 7 illustrates three areas defined in a display area configured using a data link structure capable of reducing the bezel of the display panel according to aspects of the present disclosure.

FIG. 8 is a plan view of the display panel having a data link structure capable of reducing the bezel according to aspects of the present disclosure.

FIGS. 9 and 10 are cross-sectional views of the display panel having a data link structure capable of reducing the bezel according to aspects of the present disclosure.

FIG. 11 is a plan view of the display panel according to aspects of the present disclosure having a power line structure associated with a data link structure capable of reducing the bezel.

FIG. 12 is a plan view of a partial area in the configuration of FIG. 11.

FIG. 13 illustrates some color artifacts vertically recognized in a power area located in a central portion of the display panel according to aspects of the present disclosure.

FIG. 14 is another plan view of the display panel according to aspects of the present disclosure having a power line structure associated with a data link structure capable of reducing the bezel area.

FIGS. 15 and 16 are plan views of a partial area in the configuration of FIG. 14.

### DETAILED DESCRIPTION OF THE EMBODIMENTS

Reference is now made in detail to aspects of the present disclosure, examples of which can be illustrated in the accompanying drawings. In the following description, when a detailed description of well-known methods, functions, the structures, or configurations can unnecessarily obscure aspects of the present disclosure, a detailed description of such known functions or configurations can have been omitted for brevity. Further, repetitive descriptions can be omitted for brevity. The progression of processing steps and/or operations described is a non-limiting example.

The sequence of steps and/or operations is not limited to that set forth herein and can be changed to occur in an order that is different from an order described herein, with the exception of steps and/or operations necessarily occurring in a particular order. In one or more examples, two operations in succession can be performed substantially concurrently, or the two operations can be performed in a reverse order or in a different order depending on a function or operation involved.

Unless stated otherwise, like reference numerals can refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings can have the same or substantially the same functions and properties unless stated otherwise. Names of the respective elements used in the following explanations are selected only for convenience and can be thus different from those used in actual products.

Advantages and features of the present disclosure, and implementation methods thereof, are clarified through the aspects described with reference to the accompanying drawings. The present disclosure may, however, be embodied in different forms and should not be construed as limited to the example aspects set forth herein. Rather, these example aspects are examples and are provided so that this disclosure can be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

Where a term like “comprise,” “have,” “include,” “contain,” “constitute,” “made of,” “formed of,” “composed of,” or the like is used with respect to one or more other elements (e.g., layers, films, regions, components, sections, members, parts, regions, areas, portions, steps, operations, and/or the like), one or more other elements can be added unless a term, such as “only” or the like is used. The terms used in the present disclosure are merely used in order to describe example aspects, and are not intended to limit the scope of the present disclosure. The terms of a singular form can include plural forms unless the context clearly indicates otherwise.

The word “exemplary” is used to mean serving as an example or illustration, unless otherwise specified. Aspects are example aspects. “Aspects,” “examples,” and the like should not be construed as preferred or advantageous over other implementations. An aspect, an example, an example aspect, or the like can refer to one or more aspects, one or more examples, one or more example aspects, or the like, unless stated otherwise. Further, the term “may” encompass all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range can be caused by various factors (e.g., process factors, internal or external impact, noise, or the like). In interpreting a numerical value, the value is interpreted as including an error range unless explicitly stated otherwise.

In describing a positional relationship, when the positional relationship between two parts (e.g., layers, films, regions, components, sections, or the like) is described, for example, using “on,” “upon,” “on top of,” “over,” “under,” “above,” “below,” “beneath,” “near,” “close to,” “adjacent to,” “beside,” “next to,” “at or on a side of,” or the like, one or more other parts can be located between the two parts unless a more limiting term, such as “immediate(ly),” “direct(ly),” or “close(ly),” is used. For example, where a structure is described as being positioned “on,” “upon,” “on top of,” “over,” “under,” “above,” “below,” “beneath,” “near,” “close to,” “adjacent to,” “beside,” “next to,” “at or on a side of,” or the like another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

Spatially relative terms, such as “below,” “beneath,” “lower,” “on,” “above,” “upper” and the like, can be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, can include all directions of “above” and “below.” Likewise, an exemplary term “above” or “on” can include both directions of “above” and “below.”

In describing a temporal relationship, when the temporal order is described as, for example, “after,” “subsequent,” “next,” “before,” “preceding,” “prior to,” or the like, a case that is not consecutive or not sequential can be included and thus one or more other events can occur therebetween, unless a more limiting term, such as “just,” “immediate(ly),” or “direct(ly),” is used.

The terms, such as “below,” “lower,” “above,” “upper” and the like, can be used herein to describe a relationship between element(s) as illustrated in the drawings. It will be understood that the terms are spatially relative and based on the orientation depicted in the drawings.

It is understood that, although the terms “first,” “second,” or the like can be used herein to describe various elements (e.g., layers, films, regions, components, sections, members, parts, regions, areas, portions, steps, operations, and/or the like), these elements should not be limited by these terms, for example, to any particular order, precedence, or number of elements. These terms are used only to distinguish one element from another. For example, a first element can denote a second element, and, similarly, a second element can denote a first element, without departing from the scope of the present disclosure. Furthermore, the first element, the second element, and the like can be arbitrarily named according to the convenience of those skilled in the art without departing from the scope of the present disclosure. For clarity, the functions or structures of these elements (e.g., the first element, the second element and the like) are not limited by ordinal numbers or the names in front of the elements. Further, a first element can include one or more first elements. Similarly, a second element or the like can include one or more second elements or the like.

In describing elements of the present disclosure, the terms “first,” “second,” “A”, “B”, “(a)”, or “(b)”, or the like can be used. These terms are intended to identify the corresponding element(s) from the other element(s), and these are not used to define the essence, basis, sequence, order, or number of the elements.

For the expression that an element (e.g., layer, film, region, component, section, or the like) is described as “connected,” “coupled,” “attached,” “adhered,” or the like to another element, the element can be not only directly connected, coupled, attached, adhered, or the like to another element, but also be indirectly connected, coupled, attached, adhered, or the like to another element with one or more intervening elements disposed or interposed between the elements, unless otherwise specified.

For the expression that an element (e.g., layer, film, region, component, section, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phrase that an element (e.g., layer, film, region, component, section, or the like) is “provided,” “disposed,” “connected,” “coupled,” or the like in, on, with or to another element can be understood, for example, as that at least a portion of the element is provided, disposed, connected, coupled, or the like in, on, with or to at least a portion of another element, or that the entirety of the element is provided, disposed, connected, coupled, or the like in, on, with or to another element. The phrase that an element (e.g., layer, film, region, component, section, or the like) “contacts,” “overlaps,” or the like with another element can be understood, for example, as that at least a portion of the element contacts, overlaps, or the like with a least a portion of another element, that the entirety of the element contacts, overlaps, or the like with a least a portion of another element, or that at least a portion of the element contacts, overlaps, or the like with the entirety of another element.

The terms such as a “line” or “direction” should not be interpreted only based on a geometrical relationship in which the respective lines or directions are parallel or perpendicular to each other. Such terms can mean a wider range of lines or directions within which the components of the present disclosure can operate functionally. For example, the terms “first direction,” “second direction,” and the like, such as a direction parallel or perpendicular to “x-axis,” “y-axis,” or “z-axis,” should not be interpreted only based on a geometrical relationship in which the respective directions are parallel or perpendicular to each other, and can be meant as directions having wider directivities within the range within which the components of the present disclosure can operate functionally.

The term “at least one” should be understood as including any and all combinations of one or more of the associated listed items. For example, each of the phrases “at least one of a first item, a second item, or a third item” and “at least one of a first item, a second item, and a third item”, can represent (i) a combination of items provided by two or more of the first item, the second item, and the third item and (ii) only one of the first item, the second item, and the third item.

The expression of a first element, a second elements, “and/or” a third element should be understood to encompass one of the first, second, and third elements, as well as any and all combinations of the first, second and third elements. By way of example, A, B and/or C encompass only A; only B; only C; any of A, B, and C (e.g., A, B, or C); some combinations of A, B, and C (e.g., A and B; A and C; or B and C); and all of A, B, and C. Furthermore, an expression “A/B” can be understood as A and/or B. For example, an expression “A/B” can refer to only A; only B; A or B; or A and B.

In one or more aspects, the terms “between” and “among” can be used interchangeably simply for convenience unless stated otherwise. For example, an expression “between a plurality of elements” can be understood as among a plurality of elements. In another example, an expression “among a plurality of elements” can be understood as between a plurality of elements. In one or more examples, the number of elements can be two. In one or more examples, the number of elements can be more than two. Furthermore, when an element (e.g., layer, film, region, component, sections, or the like) is referred to as being “between” at least two elements, the element can be the only element between the at least two elements, or one or more intervening elements can also be present.

In one or more aspects, the phrases “each other” and “one another” can be used interchangeably simply for convenience unless stated otherwise. For example, an expression “different from each other” can be understood as different from one another. In another example, an expression “different from one another” can be understood as different from each other. In one or more examples, the number of elements involved in the foregoing expression can be two. In one or more examples, the number of elements involved in the foregoing expression can be more than two.

In one or more aspects, the phrases “one or more among” and “one or more of” can be used interchangeably simply for convenience unless stated otherwise.

The term “or” means “inclusive or” rather than “exclusive or.” For example, unless otherwise stated or clear from the context, the expression that “x uses a or b” means any one of natural inclusive permutations. For example, “a or b” can mean “a,” “b,” or “a and b.” For example, “a, b or c” can mean “a,” “b,” “c,” “a and b,” “b and c,” “a and c,” or “a, b and c.”

Features of various aspects of the present disclosure can be partially or entirely coupled to or combined with each other, can be technically associated with each other, and can be operated, linked, or driven together in various ways. Aspects of the present disclosure can be implemented or carried out independently from each other, or can be implemented or carried out together in a co-dependent or related relationship. In one or more aspects, the components of each apparatus according to various aspects of the present disclosure can be operatively coupled and configured.

Unless otherwise defined, the terms (including technical and scientific terms) used herein have the same meaning as commonly understood by one of ordinary skill in the art to which example aspects belong. It should be further understood that terms, such as those defined in commonly used dictionaries, should be interpreted as having a meaning that is, for example, consistent with their meaning in the context of the relevant art and should not be interpreted in an idealized or overly formal sense, unless expressly defined otherwise herein.

The terms used herein have been selected as being general in the related technical field; however, there can be other terms depending on the development and/or change of technology, convention, preference of technicians, and so on. Therefore, the terms used herein should not be understood as limiting technical ideas, but should be understood as examples of the terms for describing example aspects.

Further, in a specific case, a term can be arbitrarily selected by an applicant, and in this case, the detailed meaning thereof is described herein. Therefore, the terms used herein should be understood based on not only the name of the terms, but also the meaning of the terms and the content hereof.

Here, “X-axis direction”, “Y-axis direction” and “Z-axis direction” should not be construed by a geometric relation only of a mutual vertical relation and can have broader directionality within the range that elements of the present disclosure can act functionally.

In the following description, various example aspects of the present disclosure are described in detail with reference to the accompanying drawings. With respect to reference numerals to elements of each of the drawings, the same elements can be illustrated in other drawings, and like reference numerals can refer to like elements unless stated otherwise. The same or similar elements can be denoted by the same reference numerals even though they are depicted in different drawings. In addition, for convenience of description, a scale, dimension, size, and thickness of each of the elements illustrated in the accompanying drawings can be different from an actual scale, dimension, size, and thickness, and thus, aspects of the present disclosure are not limited to a scale, dimension, size, and thickness illustrated in the drawings.

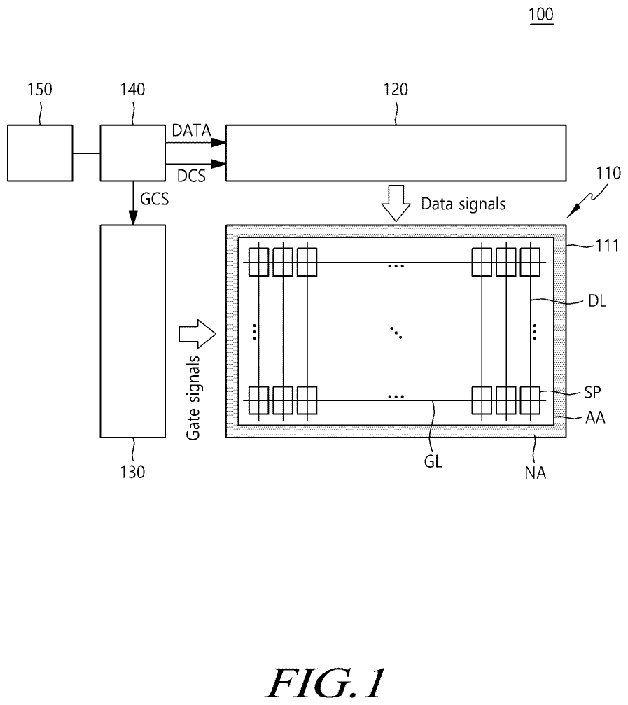

FIG. 1 illustrates a system configuration of a display apparatus 100 according to aspects of the present disclosure. All components of each display apparatus according to all aspects of the present disclosure are operatively coupled and configured.

Referring to FIG. 1, in one or more aspects, the display apparatus 100 can include a display panel 110 and a display driving circuit, as elements configured to generate and display images. The display driving circuit can be a circuit configured to drive the display panel 110, and include a data driving circuit 120, a gate driving circuit 130, a controller 140, and other circuit components. But aspects of the present disclosure are not limited thereto, and other elements can be included.

For example, the display panel 110 can include a substrate 111 and a plurality of subpixels SP disposed on the substrate 111.

The substrate 111 can include a display area AA configured to display an image to be displayed and a non-display area NA disposed outside of the display area AA.

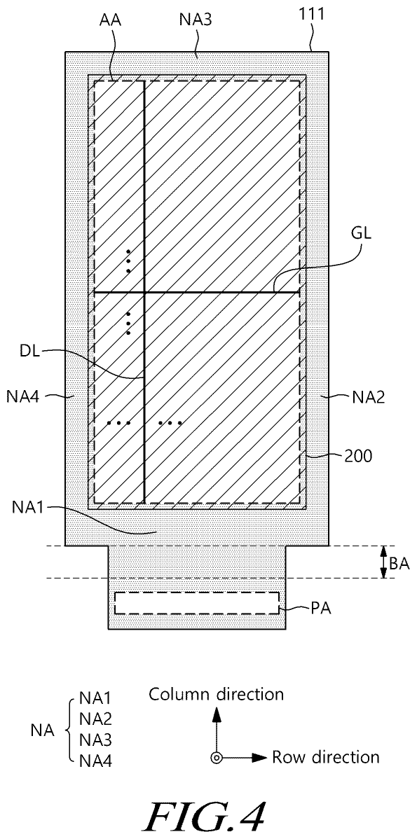

The display area AA can also be referred to as an active area, and a plurality of subpixels SP configured to display images can be disposed at the display area AA. The non-display area NA can also be referred to as a non-active area and can include a pad area PA (see FIG. 4). For example, the pad area PA can be a portion of the non-display area NA disposed in a first direction (e.g., a column direction or a row direction) from the display area AA.

According to aspects of the present disclosure, the display panel 110 can be configured to have a very small non-display area NA. For example, the non-display area NA can include a first non-display area located outside of the display area AA in the first direction, a second non-display area located outside of the display area AA in the second direction, a third non-display area located outside of the display area AA in a direction opposite to the first direction, and a fourth non-display area located outside of the display area AA in a direction opposite to the second direction. The first non-display area among the first to fourth non-display areas can include a pad area to which a driving circuit is connected or bonded (or attached). Among the first to fourth non-display areas, the second to fourth non-display areas that do not include a pad area can have a very small size compared to the first non-display area.

In another example, a boundary area between the display area AA and the non-display area NA can be defined. In this example, the non-display area NA can be bent at a certain angle to the display area AA, and thereby, can be disposed under the display area AA. In this implementation, when a user views the display apparatus 100 in front thereof, all or most of the non-display area NA can be not visible to the user.

Various types of signal lines configured to drive a plurality of subpixels SP can be disposed at the substrate 111 of the display panel 110.

In some aspects, the display apparatus 100 herein can be a liquid crystal display apparatus, or the like, or a self-emission display apparatus in which light is emitted from the display panel 110 itself. In an example where the display apparatus 100 is the self-emission display apparatus, each of the plurality of subpixels SP can include a light emitting element. But aspects of the present disclosure are not limited thereto.

For example, the display apparatus 100 according to aspects of the present disclosure can be an organic light emitting display apparatus in which the light emitting element is implemented using an organic light emitting diode (OLED). In another example, the display apparatus 100 according to aspects of the present disclosure can be an inorganic light emitting display apparatus in which the light emitting element is implemented using an inorganic material-based light emitting diode. In another example, the display apparatus 100 according to aspects of the present disclosure can be a quantum dot display apparatus in which the light emitting element is implemented using quantum dots, which are self-emission semiconductor crystals.

The structure of each of the plurality of subpixels SP can depend on types of display apparatus 100. For example, in an example where the display apparatus 100 is a self-emission display apparatus including self-emission subpixels SP, each subpixel SP can include a self-emission light emitting element, one or more transistors, and one or more capacitors. But aspects of the present disclosure are not limited thereto.

The various types of signal lines can include, for example, a plurality of data lines DL for carrying data signals (which can be referred to as data voltages or image signals), a plurality of gate lines GL for carrying gate signals (which can be referred to as scan signals), and the like. But aspects of the present disclosure are not limited thereto.

In one or more aspects, the plurality of data lines DL and the plurality of gate lines GL can intersect one another. The plurality of data lines DL can be disposed such that they extend in a first direction, and the plurality of gate lines GL can be disposed such that they extend in a second direction. For example, the first direction can be the column direction, and the second direction can be the row direction. In another example, the first direction can be the row direction, and the second direction can be the column direction. Hereinafter, for convenience of explanation, discussions can be provided based on examples where each of a plurality of data lines DL is disposed in the column direction, and each of a plurality of gate lines GL is disposed in the row direction, but aspects of the present disclosure are limited thereto.

The data driving circuit 120 can be a circuit configured to drive a plurality of data lines DL and can output data signals to the plurality of data lines DL.

The data driving circuit 120 can receive image data DATA in digital form from the controller 140, convert the received image data DATA into data signals in analog form, and output converted data signals to the plurality of data lines DL.

In some aspects, the data driving circuit 120 can be connected to the display panel 110 by a tape-automated-bonding (TAB) method, or connected to a conductive pad such as a bonding pad of the display panel 110 by a chip-on-glass (COG) method or a chip-on-panel (COP) method, or connected to the display panel 110 by a chip-on-film (COF) method. However, aspects of the present disclosure are not limited thereto.

The data driving circuit 120 can be disposed at, and/or electrically connected to, but not limited to, one side or one portion (e.g., an upper portion or a lower portion) of the display panel 110. In some aspects, the data driving circuit 120 can be disposed at, and/or electrically connected to, but not limited to, two sides or portions (e.g., an upper portion and a lower portion) of the display panel 110 or at least two of four sides or portions (e.g., the upper portion, the lower portion, a left portion, and a right portion) of the display panel 110 according to driving schemes, panel design schemes, or the like.

The data driving circuit 120 can be connected to outside, or a periphery, of the display area AA of the display panel 110, or be disposed in the display area AA of the display panel 110.

The gate driving circuit 130 can be a circuit configured to drive a plurality of gate lines GL and can output gate signals to the plurality of gate lines GL.

The gate driving circuit 130 can receive various types of gate driving control signals GCS, and further, receive a first gate voltage corresponding to a turn-on level voltage and a second gate voltage corresponding to a turn-off level voltage. Thereby, the gate driving circuit 130 can generate gate signals and supply the generated gate signals to the plurality of gate lines GL.

In some aspects, the gate driving circuit 130 in the display apparatus 100 can be embedded into the display panel 110 by a gate-in-panel (GIP) method. In an example where the gate driving circuit 130 is implemented by the gate-in-panel (GIP) method, the gate driving circuit 130 can be disposed on the substrate 111 of the display panel 110 during the manufacturing process of the display panel 110 or display apparatus 100. But aspects of the present disclosure are not limited thereto.

In one aspect, the gate driving circuit 130 can be disposed at the non-display area NA of the display panel 110.

In another aspect, the gate driving circuit 130 can be disposed at the display area AA of the display panel 110. In this implementation, for example, the gate driving circuit 130 can be disposed at, and/or electrically connected to, but not limited to, some of a first area (e.g., a left area or a right area) of the display area AA of the display panel 110. In another example, the gate driving circuit 130 can be disposed at, and/or electrically connected to, but not limited to, some of a first area (e.g., a left area or a right area) and some of a second area (e.g., the right area or the left area) of the display area AA of the display panel 110.

Herein, the gate driving circuit 130 embedded in the display panel 110 by the gate-in-panel (GIP) method can also be referred to as a “gate-in-panel circuit.”

The controller 140 can be a device configured to control the data driving circuit 120 and the gate driving circuit 130, and can control driving timing for the plurality of data lines DL and driving timing for the plurality of gate lines GL.

The controller 140 can supply a data control signal DCS to the data driving circuit 120 to control the data driving circuit 120, and supply a gate control signal GCS to the gate driving circuit 130 to control the gate driving circuit 130.

The controller 140 can receive image data input from a host system 150 and supply image data DATA readable by the data driving circuit 120 based on the input image data to the data driving circuit 120.

The controller 140 can be implemented in a separate component from the data driving circuit 120, or integrated with the data driving circuit 120, so that the controller 140 and the data driving circuit 120 can be implemented in a single integrated circuit.

The controller 140 can be a timing controller used in the display technology or a control apparatus/device capable of additionally performing other control functionalities in addition to the function of the timing controller. In one or more aspects, the controller 140 can be one or more other control circuits different from the timing controller, or a circuit or component in the control apparatus/device. The controller 140 can be implemented using various circuits or electronic components such as an integrated circuit (IC), a field programmable gate array (FPGA), an application specific integrated circuit (ASIC), a processor, and/or the like, but aspects of the present disclosure are not limited thereto.

The controller 140 can be mounted on a printed circuit board, a flexible printed circuit, or the like, and can be electrically connected to the data driving circuit 120 and the gate driving circuit 130 through the printed circuit board, the flexible printed circuit, and/or the like.

The controller 140 can transmit signals to, and receive signals from, the data driving circuit 120 via one or more predetermined interfaces. For example, such interfaces can include a low voltage differential signaling (LVDS) interface, an embedded clock point-point interface (EPI), a serial peripheral interface (SPI), and the like. However, aspects of the present disclosure are not limited thereto.

In one or more aspects, to provide a touch sensing function, as well as an image display function, the display apparatus 100 can include a touch sensor, and a touch sensing circuit configured to sense the touch sensor and detect the presence or absence of a touch by an object such as a finger, a pen, or the like, or the location of the touch.

The touch sensing circuit can include a touch driving circuit configured to drive and sense the touch sensor and generate and output touch sensing data, and a touch controller capable of detecting the presence or absence of a touch or the location of the touch by the touch sensing data.

The touch sensor can include a plurality of touch electrodes. The touch sensor can further include a plurality of touch lines to electrically connect the plurality of touch electrodes to the touch driving circuit.

The touch sensor can be disposed outside of the display panel 110 in the form of a touch panel or can be disposed inside of the display panel 110. The touch sensor disposed outside of the display panel 110 can be referred to as an add-on type touch sensor. In the example where the add-on type of touch sensor is disposed in the display apparatus 100, the touch panel and the display panel 110 can be separately manufactured and combined in an assembly process. The add-on type of touch panel can include a touch panel substrate and a plurality of touch electrodes disposed on the touch panel substrate.

In the example where the touch sensor is disposed inside of the display panel 110, the touch sensor can be formed on the substrate along with signal lines and electrodes related to display driving during the manufacturing process of the display panel 110.

The touch driving circuit can supply a touch driving signal to at least one of a plurality of touch electrodes and generate touch sensing data by sensing at least one of the plurality of touch electrodes.

The touch sensing circuit can perform touch sensing by a self-capacitance sensing method or a mutual-capacitance sensing method.

In the example where the touch sensing circuit performs touch sensing by the self-capacitance sensing method, the touch sensing circuit can perform touch sensing based on a capacitance between one or more touch electrode and an object such as a finger, a pen, and/or the like. According to the self-capacitance sensing method, each of a plurality of touch electrodes can serve as both a driving touch electrode and a sensing touch electrode. The touch driving circuit can drive all, or one or more, of a plurality of touch electrodes and sense all, or one or more, of the plurality of touch electrodes.

In the example where the touch sensing circuit performs touch sensing by the mutual-capacitance sensing method, the touch sensing circuit can perform touch sensing based on a capacitance between touch electrodes. According to the mutual-capacitance sensing method, a plurality of touch electrodes can be divided into driving touch electrodes and sensing touch electrodes. The touch driving circuit can drive the driving touch electrodes and sense the sensing touch electrodes.

In one or more aspects, the touch driving circuit and touch controller included in the touch sensing circuit can be implemented in separate devices or in a single device. In one or more aspects, the touch driving circuit and the data driving circuit can be implemented in separate devices or in a single device.

The display apparatus 100 can further include a power supply circuit configured to supply various types of power to the display driving circuit and/or the touch sensing circuit.

In some aspects, the display apparatus 100 can be a mobile terminal such as a smart phone, a tablet, or the like, or a monitor, a television (TV), or the like. Such apparatuses can be configured in various types, sizes, and shapes. The display apparatus 100 according to aspects of the present disclosure are not limited thereto, and can include various types, sizes, and shapes configured to display information or images.

In one or more aspects, the display apparatus 100 can further include an electronic apparatus such as a camera (e.g., an image sensor), a sensor capable of detecting an object, and the like. For example, the sensor can be a sensor capable of detecting an object or a human body by receiving light such as infrared light, ultrasonic light, ultraviolet light or the like. But aspects of the present disclosure are not limited thereto.

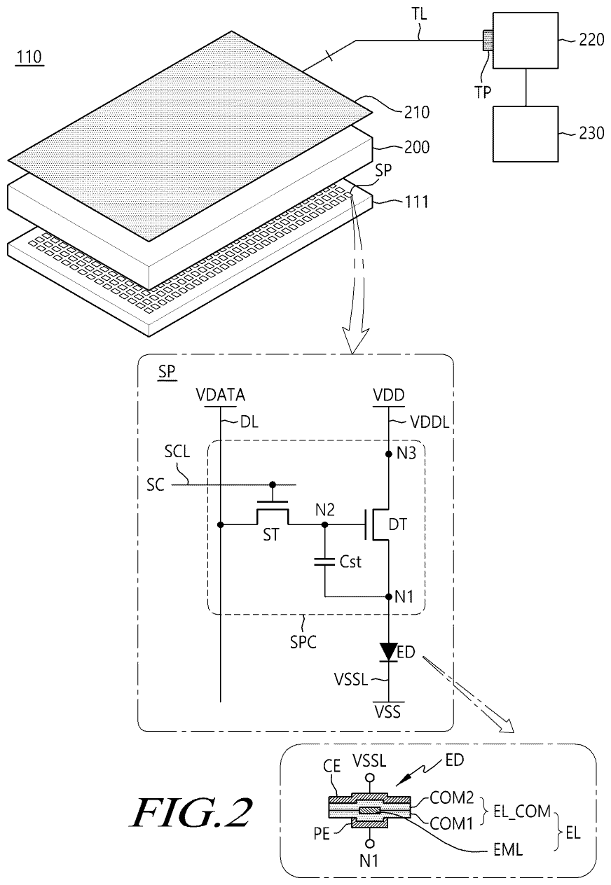

FIG. 2 illustrates a configuration of the display panel 110 according to aspects of the present disclosure.

Referring to FIG. 2, the display panel 110 can include a substrate 111 on which a plurality of subpixels SP are disposed, and an encapsulation layer 200 over the substrate 111. The encapsulation layer 200 can also be referred to as an encapsulation substrate, an encapsulation part, or the like. But aspects of the present disclosure are not limited thereto.

Referring to FIG. 2, in an example where the display apparatus 100 is a self-emission display apparatus, each of the plurality of subpixels SP disposed on the substrate 111 can include a light emitting element ED and a subpixel circuit SPC configured to drive the light emitting element ED.

Referring to FIG. 2, the subpixel circuit SPC can include a plurality of transistors and at least one capacitor configured to drive the light emitting element ED. The subpixel circuit SPC can drive the light emitting element ED by supplying a driving current to the light emitting element ED at a predetermined timing. The light emitting element ED can emit light by being driven by the driving current.

The plurality of transistors can include a driving transistor DT configured to drive the light emitting element ED and a scan transistor ST configured to be turned on or off according to a scan signal SC.

The driving transistor DT can supply a driving current to the light emitting element ED.

The scan transistor ST can be configured to control an electrical state of a corresponding node in the subpixel circuit SPC or to control the state or operation of the driving transistor DT.

The at least one capacitor can include a storage capacitor Cst configured to maintain a constant voltage during a frame or a certain period of the frame.

To drive one or more subpixels SP, a data signal VDATA, which is an image signal, and a scan signal SC, which is a gate signal, can be applied to the subpixel SP. Further, a common pixel driving voltage including a first common driving voltage VDD and a second common driving voltage VSS can be applied to the one or more subpixels SP.

The light emitting element ED can include a pixel electrode PE, an intermediate layer EL, and a common electrode CE. The intermediate layer EL can be disposed between the pixel electrode PE and the common electrode CE. But aspects of the present disclosure are not limited thereto.

For example, the pixel electrode PE can be an electrode disposed at each subpixel SP, and the common electrode CE can be an electrode commonly disposed at a plurality of subpixels SP. For example, the pixel electrode PE can be an anode, and the common electrode CE can be a cathode. In another example, the pixel electrode PE can be a cathode, and the common electrode CE can be an anode. Hereinafter, for convenience of explanation, discussions can be provided based on examples where the pixel electrode PE is an anode, and the common electrode CE is a cathode.

In an example where the light emitting element ED is an organic light emitting diode, the intermediate layer EL can include an emission layer EML, a first common intermediate layer COM1 between the pixel electrode PE and the emission layer EML, and a second common intermediate layer COM2 between the emission layer EML and the common electrode CE. A layer including the first common intermediate layer COM1 and the second common intermediate layer COM2 can be referred to as a common intermediate layer EL_COM.

The emission layer EML can be disposed at each subpixel SP, and the common intermediate layer EL_COM can be commonly disposed across a plurality of subpixels SP.

The emission layer EML can be disposed at each light emitting area, and the common intermediate layer EL_COM can be commonly disposed across a plurality of light emitting areas and a non-light emitting area. But aspects of the present disclosure are not limited thereto.

For example, the first common intermediate layer COM1 can include a hole injection layer (HIL), a hole transport layer (HTL), and the like. The second common intermediate layer COM2 can include an electron transport layer (ETL), an electron injection layer (EIL), and the like. But aspects of the present disclosure are not limited thereto.

The hole injection layer can inject holes from the pixel electrode PE to the hole transport layer, the hole transport layer can transport holes to the emission layer EML, the electron injection layer can inject electrons from the common electrode CE to the electron transport layer, and the electron transport layer can transport electrons to the emission layer EML. But aspects of the present disclosure are not limited thereto.

For example, the common electrode CE can be electrically connected to a second common driving voltage line VSSL. A second common driving voltage VSS, which is a type of common pixel driving voltage, can be applied to the common electrode CE through the second common driving voltage line VSSL. The pixel electrode PE can be electrically connected directly or indirectly (via another transistor) to a first node N1 of the corresponding driving transistor DT of each subpixel SP. Herein, the second common driving voltage VSS can also be referred to as a “base voltage”, and the second common driving voltage line VSSL can also be referred to as a “low power supply voltage line”, a “low voltage line”, or a “base voltage line.

Each light emitting element ED can be configured by overlapping of the pixel electrode PE, the emission layer in the intermediate layer EL, and the common electrode CE. Each light emitting element ED can form a corresponding light emitting area. For example, a corresponding light emitting area of each light emitting element ED can include an overlapping area of the pixel electrode PE, the emission layer in the intermediate layer EL, and the common electrode CE.

In some aspects, the light emitting element ED can be an organic light emitting diode (OLED), an inorganic material-based light emitting diode (LED), or a quantum dot light emitting element. For example, in an example where the light emitting element ED is an organic light emitting diode OLED, the intermediate layer EL of the light emitting element ED can be a layer including an organic material.

The driving transistor DT can be a transistor configured to supply a driving current to the light emitting element ED. The driving transistor DT can be connected between a first common driving voltage line VDDL and the light emitting element ED.

The driving transistor DT can include a first node N1, a second node N2, and a third node N3. The first node N1 can be electrically connected to the light emitting element ED. A data signal VDATA can be applied to the second node N2. The first common driving voltage VDD supplied through the first common driving voltage line VDDL can be applied to the third node N3.

In the driving transistor DT, the second node N2 can be a gate node, the first node N1 can be a source node or a drain node, and the third node N3 can be the drain node or the source node. Hereinafter, for merely convenience of explanation, discussions can be provided based on examples where the first, second, and third nodes (N1, N2, and N3) of the driving transistor DT are source, gate, and drain nodes, respectively. However, aspects of the present disclosure are not limited thereto.

The scan transistor ST in the subpixel circuit SPC illustrated in FIG. 2 can be a switching transistor configured to allow a data signal VDATA, which is an image signal, to be supplied to the second node N2, which is the gate node of the driving transistor DT. But aspects of the present disclosure are not limited thereto.

The scan transistor ST can be turned on or turned off by a scan signal SC, which is a type of gate signal, applied through a scan line SCL, which is a type of gate line GL, and control an electrical connection between the second node N2 of the driving transistor DT and a data line DL. The drain electrode or source electrode of the scan transistor ST can be electrically connected to the data line DL. The source electrode or drain electrode of the scan transistor ST can be electrically connected to the second node N2 of the driving transistor DT. The gate electrode of the scan transistor ST can be electrically connected to the scan line SCL.

The storage capacitor Cst can be electrically connected between the first node N1 and the second node N2 of the driving transistor DT. The storage capacitor Cst can include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst can be an external capacitor intentionally designed to be located outside of the driving transistor DT, and therefore, be different from an internal capacitor such as a parasitic capacitor (e.g., a Cgs, a Cgd) that can be formed between the first node N1 and the second node N2 of the driving transistor DT.

Each of the driving transistor DT and the scan transistor ST can be an n-type transistor or a p-type transistor.

The display panel 110 can have a top emission structure or a bottom emission structure.

In an example where the display panel 110 has the top emission structure, at least a portion of the subpixel circuit SPC can overlap with at least a portion of the light emitting element ED in the vertical direction. In this configuration, the area or size of a corresponding light emitting area can be increased, and a corresponding aperture ratio can be increased.

In an example where the display panel 110 has the bottom emission structure, the subpixel circuit SPC can be not overlapping the light emitting element ED in the vertical direction.

As shown in FIG. 2, the subpixel circuit SPC can include two transistors (2T: DT and ST) and one capacitor (1C: Cst) (which can be referred to as a “2T1C structure”), and in some implementations, can further include one or more transistors, or further include one or more capacitors. But aspects of the present disclosure are not limited thereto.

For example, the subpixel circuit SPC can have an 8T1C structure including 8 transistors and 1 capacitor. In another example, the subpixel circuit SPC can have an 6T2C structure including 6 transistors and 2 capacitor. In further another example, the subpixel circuit SPC can have a 7T1C structure including 7 transistors and 1 capacitor. Aspects of the present disclosure are not limited to such structures. But aspects of the present disclosure are not limited thereto.

The types and number of gate signals supplied to a subpixel SP, and/or the types and number of gate lines connected to the subpixel SP can vary depending on a structure of a corresponding subpixel circuit SPC. Further, the types and number of common pixel driving voltages supplied to a subpixel SP can vary depending on a structure of a corresponding subpixel circuit SPC.

Since circuit elements (e.g., a light emitting element ED such as an organic light emitting diode (OLED) including an organic material) in each subpixel SP are vulnerable to external moisture or oxygen, an encapsulation layer 200 can be disposed at the display panel 110 to prevent the external moisture or oxygen from penetrating into the circuit elements (e.g., the light emitting element ED). The encapsulation layer 200 can be disposed in various shapes or configurations to prevent light emitting elements ED from contacting moisture or oxygen. For example, the encapsulation layer 200 can include two or more layers in which organic and inorganic layers are alternately stacked, but aspects of the present disclosure are not limited thereto.

Referring to FIG. 2, in some aspects, to sense a touch of a user, the display apparatus 100 can include a touch sensor part 210 including a plurality of sensor electrodes, a touch driving circuit 220 configured to sense the plurality of sensor electrodes, and a touch controller 230 configured to determine the presence or absence of a touch or touch coordinates using the sensing result (e.g., touch sensing data) of the touch driving circuit 220.

The touch sensor part 210 can be embedded in the display panel 110. For example, the touch sensor part 210 can be disposed on the encapsulation layer 200 of the display panel 110.

The display panel 110 can include a plurality of touch pads TP to which the touch driving circuit 220 is electrically connected, and a plurality of touch routing lines TL for electrically connecting the plurality of sensor electrodes included in the touch sensor part 210 to the plurality of touch pads TP to which the touch driving circuit 220 is connected.

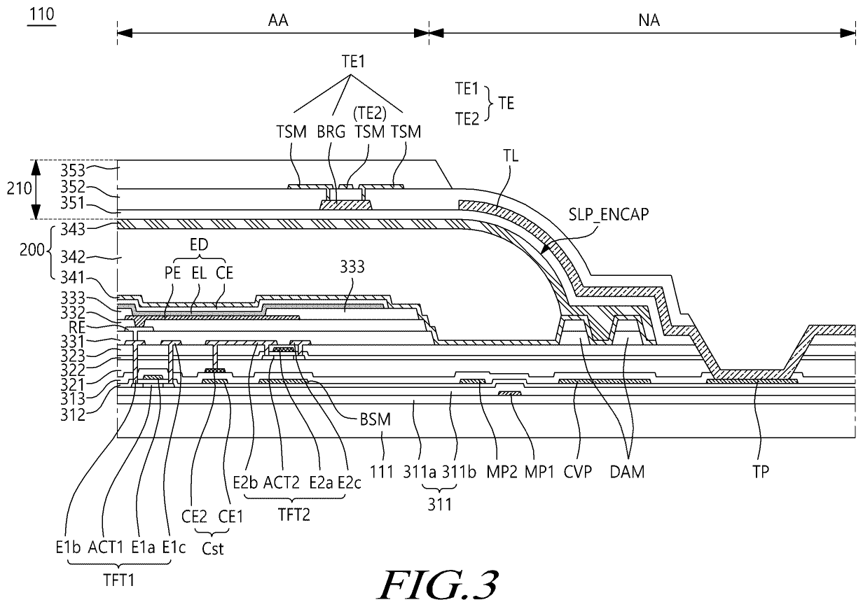

FIG. 3 is a cross-sectional view of the display panel 110 according to aspects of the present disclosure.

Referring to FIG. 3, in some aspects, in terms of stack-up configuration, the display panel 110 can include a transistor forming part, a light emitting element forming part, and an encapsulation part. But aspects of the present disclosure are not limited thereto.

The transistor forming part can include a substrate 111, various types of insulating layers (311, 312, 313, 321, 322, and 323) on the substrate 111, various types of transistors (TFT1 and TFT2), a storage capacitor Cst, and various electrodes or signal lines. A transistor forming part can be a transistor part.

The transistors (TFT1 and TFT2) in the transistor forming part can include a first transistor TFT1 and a second transistor TFT2.

The first transistor TFT1 can include a first active layer ACT1, a first electrode E1a, a second electrode E1b, and a third electrode E1c. The first active layer ACT1 can be a first semiconductor layer, but aspects of the present disclosure are not limited thereto. For example, the first active layer ACT1 can be configured with an oxide semiconductor, amorphous silicon, polysilicon, low-temperature polysilicon (LTPS), or the like, but aspects of the present disclosure are not limited thereto. The first transistor TFT1 can be a p-channel transistor or an n-channel transistor, but aspects of the present disclosure are not limited thereto. The first electrode E1a can be a gate electrode, the second electrode E1b can be a source electrode or a drain electrode, and the third electrode E1c can be the drain electrode or the source electrode. Hereinafter, for convenience of explanation, discussions can be provided based on examples where the first, second, and third electrodes (E1a, E1b, and E1c) are a first gate electrode E1a, a first source electrode E1b, and a first drain electrode E1c, respectively.

The second transistor TFT2 can include a second active layer ACT2, a fourth electrode E2a, a fifth electrode E2b, and a sixth electrode E2c. The second active layer ACT2 can be a second semiconductor layer, but aspects of the present disclosure are not limited thereto. For example, the second active layer ACT2 can be configured with an oxide semiconductor, amorphous silicon, polysilicon, low-temperature polysilicon (LTPS), or the like, but aspects of the present disclosure are not limited thereto. The second transistor TFT2 can be a p-channel transistor or an n-channel transistor, but aspects of the present disclosure are not limited thereto. For example, one of the first transistor TFT1 and the second transistor TFT2 can include an active layer having an oxide semiconductor. In another example, one of the first transistor TFT1 and the second transistor TFT2 can include an active layer having low-temperature polysilicon. In another example, the first transistor TFT1 and the second transistor TFT2 can include an active layer configured to have an oxide semiconductor. In another example, one or more transistors in a gate driver configured in the gate-in-panel (GIP) type can include active layers having an oxide semiconductor or low temperature polysilicon. In another example, all transistors configured on the substrate and transistors included in a gate driver configured in the gate-in-panel (GIP) type can include active layers having an oxide semiconductor. But aspects of the present disclosure are not limited thereto.

The fourth electrode E2a can be a gate electrode, the fifth electrode E2b can be a source electrode or a drain electrode, and the sixth electrode E2c can be the drain electrode or the source electrode. Hereinafter, for convenience of explanation, discussions can be provided based on examples where the fourth, fifth, and sixth electrodes (E2a, E2b, and E2c) are a second gate electrode E2a, a second source electrode E2b, and a second drain electrode E2c, respectively.

The second active layer ACT2 of the second transistor TFT2 can be disposed higher from the substrate 111 than the first active layer ACT1 of the first transistor TFT1.

A first buffer layer 311 can be disposed under the first active layer ACT1 of the first transistor TFT1, and a second buffer layer 321 can be disposed under the second active layer ACT2 of the second transistor TFT2. For example, the first active layer ACT1 of the first transistor TFT1 can be disposed on the first buffer layer 311, and the second active layer ACT2 of the second transistor TFT2 can be disposed on the second buffer layer 321. The second buffer layer 321 can be disposed higher than the first buffer layer 311.

The storage capacitor Cst can be disposed in various metal layers in the display panel 110. For example, the storage capacitor Cst can include a first capacitor electrode CE1 and a second capacitor electrode CE2.

The light emitting element forming part can include a plurality of light emitting elements ED disposed on at least one planarization layer (331, and/or 332). Each of the light emitting elements ED can include a pixel electrode PE, an intermediate layer EL, and a common electrode CE. The light emitting element forming part can be the light emitting element part.

The encapsulation part can include an encapsulation layer 200 on the plurality of light emitting elements ED. The encapsulation layer 200 can be configured in a single layer or multiple layers. In addition to the encapsulation layer 200, the encapsulation part can further include at least one dam DAM. But aspects of the present disclosure are not limited thereto.

Hereinafter, the stack-up configuration of the display panel 110 according to aspects of the present disclosure will be described in more detail with reference to FIG. 3.

Referring to FIG. 3, the first buffer layer 311 can be disposed on the substrate 111. The first buffer layer 311 can be configured in a single layer or multiple layers. In an example where the first buffer layer 311 has a stack of multiple layers, the first buffer layer 311 can include a multi-buffer layer 311a and a buffer layer 311b.

The first active layer ACT1 of the first transistor TFT1 can be disposed on the first buffer layer 311. The first active layer ACT1 can include a channel region where a channel is configured, a source connection region on one side of the channel region, and a drain connection region on another side of the channel region.

A first gate insulating layer 312 can be disposed on the first active layer ACT1 of the first transistor TFT1. The first gate electrode E1a of the first transistor TFT1 can be disposed on the first gate insulating layer 312. A first interlayer insulating layer 313 can be disposed on the first gate electrode E1a of the first transistor TFT1.

The second buffer layer 321 can be disposed on the first interlayer insulating layer 313.

The second active layer ACT2 of the second transistor TFT2 can be disposed on the second buffer layer 321. The second active layer ACT2 can include a channel region where a channel is configured, a source connection region on a first side of the channel region, and a drain connection region on a second opposing side of the channel region.

A second gate insulating layer 322 can be disposed on the second active layer ACT2 of the second transistor TFT2. The second gate electrode E2a of the second transistor TFT2 can be disposed on the second gate insulating layer 322. A second interlayer insulating layer 323 can be disposed on the second gate electrode E2a of the second transistor TFT2.

The first source electrode E1b and the first drain electrode E1c of the first transistor TFT1 and the second source electrode E2b and the second drain electrode E2c of the second transistor TFT2 can be disposed on the second interlayer insulating layer 323.

The first source electrode E1b and the first drain electrode E1c of the first transistor TFT1 can be connected to the source connection region and the drain connection region of the first active layer ACT1 respectively through respective holes of the second interlayer insulating layer 323, the second gate insulating layer 322, the second buffer layer 321, the first interlayer insulating layer 313, and the first gate insulating layer 312.

The second source electrode E2b and the second drain electrode E2c of the second transistor TFT2 can be connected to the source connection region and drain connection region of the second active layer ACT2 respectively through respective holes of the second interlayer insulating layer 323 and the second gate insulating layer 322.

The first source electrode E1b and the first drain electrode E1c of the first transistor TFT1 and the second source electrode E2b and the second drain electrode E2c of the second transistor TFT2 can include a first metal and can be disposed in a first metal layer. The first metal and the first metal layer can be referred to as a first source-drain metal and a first source-drain metal layer, respectively.

Referring to FIG. 3, in one or more aspects, the storage capacitor Cst can be configured with the first capacitor electrode CE1 and the second capacitor electrode CE2. In one or more aspects, the storage capacitor Cst can include three or more capacitor electrodes, or can include two or more capacitors connected in parallel.

Each of the first capacitor electrode CE1 and the second capacitor electrode CE2 can be disposed in various metal layers in or at the display panel 110.

In one or more aspects, the first capacitor electrode CE1 can include the same first gate metal as the first gate electrode E1a of the first transistor TFT1 on the first gate insulating layer 312, and be disposed in or at a first gate metal layer.

In one or more aspects, the second capacitor electrode CE2 can be disposed on the first interlayer insulating layer 313.

The second source electrode E2b of the second transistor TFT2 can be electrically connected to the second capacitor electrode CE2 through respective holes of the second interlayer insulating layer 323, the second gate insulating layer 322, and the second buffer layer 321.

In one or more aspects, the first transistor TFT1 can be the driving transistor DT of FIG. 2, and the second transistor TFT2 can be the scan transistor ST of FIG. 2.

The transistor forming part can further include various metal layers (e.g., a first metal layer MP1, a second metal layer MP2, and the like). For example, the first metal layer MP1 can be disposed between the multi-buffer layer 311a and the buffer layer 311b included in the first buffer layer 311. The second metal layer MP2 can include the same first gate metal as the first gate electrode E1a of the first transistor TFT1 and can be disposed in the first gate metal layer. In one or more aspects, the first metal layer MP1 can be a first metal pattern, and the second metal layer MP2 can be a second metal pattern. However, aspects of the present disclosure are not limited thereto.

Each of the first metal layer MP1 and the second metal layer MP2 can be disposed in the display area AA or the non-display area NA.

Referring to FIG. 3, the transistor forming part can further include a shielding layer BSM disposed on the substrate 111, overlapping with the second active layer ACT2 of the second transistor TFT2, and disposed under the second active layer ACT2 of the second transistor TFT2. But aspects of the present disclosure are not limited thereto.

For example, the shielding layer BSM can be disposed in the same first gate metal layer as the first gate electrode E1a of the first transistor TFT1. In another example, the shielding layer BSM can be disposed in the same metal layer as the first metal layer MP1 on the first buffer layer 311.

An additional shielding layer BSM can be disposed under the first active layer ACT1 of the first transistor TFT1 and overlap with the first active layer ACT1 of the first transistor TFT1. In this implementation, the additional shielding layer BSM can be disposed in the same metal layer as the first metal layer MP1.

Referring to FIG. 3, the transistor forming part can further include a common driving voltage pattern CVP to which a common driving voltage is applied. The common driving voltage applied to the common driving voltage pattern CVP can be a power signal, and for example, can be the first common driving voltage VDD or the second common driving voltage VSS in FIG. 2. The first common driving voltage VDD can be referred to as a high power supply voltage (or a high-potential power signal), and the second common driving voltage VSS can be referred to as a low power supply voltage (or a low-potential power signal) or a base voltage (or lower voltage).

The common driving voltage pattern CVP can be disposed in the display area AA or the non-display area NA.

At least one planarization layer can be disposed on the first transistor TFT1 and the second transistor TFT2. FIG. 3 illustrates, for example, two planarization layers (first and second planarization layers 331 and 332) disposed on the first transistor TFT1 and the second transistor TFT2. In one or more aspects, three or more planarization layers can be disposed on the first transistor TFT1 and the second transistor TFT2. However, aspects of the present disclosure are not limited thereto.

Referring to FIG. 3, the first planarization layer 331 can be disposed on the first source electrode E1b and the first drain electrode E1c of the first transistor TFT1 and the second source electrode E2b and the second drain electrode E2c of the second transistor TFT2. In one or more aspects, the first planarization layer 331 can be disposed and cover both the first transistor TFT1 and the second transistor TFT2.

Referring to FIG. 3, a connection electrode RE can be disposed on the first planarization layer 331. The connection electrode RE can be electrically connected to the first source electrode E1b of the first transistor TFT1 through a hole of the first planarization layer 331. The connection electrode RE can be referred to as a relay electrode RE.

The connection electrode RE can be disposed in a second metal layer on the first planarization layer 331, and include a second metal. The second metal and the second metal layer can be referred to as a second source-drain metal and a second source-drain metal layer, respectively.

The second planarization layer 332 can be disposed on the connection electrode RE.

Referring to FIG. 3, the light emitting element forming part can be disposed on the second planarization layer 332. A light emitting element ED can be disposed on the second planarization layer 332. The light emitting element ED can include a pixel electrode PE, an intermediate layer EL, and a common electrode CE. The light emitting area of the light emitting element ED can be formed in an area where the pixel electrode PE, the intermediate layer EL, and the common electrode CE overlap and contact each other.

The pixel electrode PE can be disposed on the second planarization layer 332, and a bank 333 can be disposed on the pixel electrode PE. An opening of the bank 333 can expose a portion of the pixel electrode PE to form the light emitting area. For example, the opening of the bank 333 can overlap with a portion of the pixel electrode PE.

The intermediate layer EL of the light emitting element ED can be disposed on a portion of the pixel electrode PE and the bank 333. The common electrode CE can be disposed on the intermediate layer EL.

Referring to FIG. 3, the encapsulation part can be disposed on the light emitting element forming part, and be disposed on the common electrode CE. The encapsulation part can include an encapsulation layer 200 disposed on the common electrode CE.

The encapsulation layer 200 can prevent moisture or oxygen from penetrating into the light emitting element ED. For example, the encapsulation layer 200 can prevent moisture or oxygen from penetrating into an organic material contained in the intermediate layer EL of the light emitting element ED. In one or more aspects, the encapsulation layer 200 can be configured in a single layer or multiple layers, but aspects of the present disclosure are not limited thereto.

Referring to FIG. 3, for example, the encapsulation layer 200 can include a first encapsulation layer 341, a second encapsulation layer 342, and a third encapsulation layer 343. The first encapsulation layer 341 and the third encapsulation layer 343 can include, for example, an inorganic layer, and the second encapsulation layer 342 can include, for example, an organic layer.

In one or more aspects, a touch sensor can be embedded in the display panel 110. In these aspects, the display panel 110 can include a touch sensor part 210 disposed on the encapsulation layer 200.

Referring to FIG. 3, the touch sensor part 210 can include a plurality of touch electrodes TE, and can include touch sensor electrodes TSM and bridge electrodes BRG to form the plurality of touch electrodes TE. The touch sensor electrodes TSM can also be referred to as touch sensor layers TSM. The bridge electrodes BRG can also be referred to as bridge layers BRG.

The touch sensor part 210 can further include one or more insulating layers such as a buffer layer 351 on the encapsulation layer 200, an interlayer insulating layer 352 on the buffer layer 351, and/or a protection layer 353 on the interlayer insulating layer 352. The bridge layers BRG can be disposed between the buffer layer 351 and the interlayer insulating layer 352, and the touch sensor layers TSM can be disposed between the interlayer insulating layer 352 and the protection layer 353.

Each of the plurality of touch electrodes TE can include a touch sensor layer TSM. Each of the plurality of touch electrodes TE can be a mesh-type electrode having a plurality of openings.

The plurality of touch electrodes TE can include one or more first touch electrodes TE1 and one or more second touch electrodes TE2. Touch sensor layers TSM included in a first touch electrode TE1 can be electrically connected through at least one bridge layer BRG.

The buffer layer 351 can be disposed on the encapsulation layer 200, the bridge layers BRG can be disposed on the buffer layer 351, and the interlayer insulating layer 352 can be disposed on the bridge layers BRG.

The touch sensor layers TSM can be disposed on the interlayer insulating layer 352. Respective portions of the touch sensor layers TSM can be connected to corresponding bridge layers BRG through holes of the interlayer insulating layer 352.

Referring to FIG. 3, the touch sensor layers TSM and bridge layers BRG can be disposed such that the touch sensor layers TSM and bridge layers BRG do not overlap with each other. The touch sensor layers TSM and bridge layers BRG can overlap with the bank 333.

In one or more aspects, a plurality of touch sensor layers TSM can be included in one touch electrode TE, and can be disposed in a mesh pattern and electrically connected to each other. In one or more aspects, one or more of touch sensor layers TSM and other one or more of the touch sensor layers TSM can be electrically connected to each other through one or more bridge layers BRG to form one touch electrode TE.

The protection layer 353 can be disposed on and cover the touch sensor layers TSM and the bridge layers BRG.

Referring to FIG. 3, a touch line TL can electrically connect a touch electrode TE to a touch pad TP. The touch line TL can include at least one of a touch sensor layer TSM and a bridge layer BRG.

In an example where the display panel 110 is a display panel in which a touch sensor is embedded, the touch line TL can extend along an outer slope SLP_ENCAP of the encapsulation layer 200 and an upper portion of at least one dam DAM and extend to the touch pad TP located in the non-display area NA.

FIG. 4 illustrates a substrate (e.g., the substrate 111 of FIG. 3) of the display panel 110 according to aspects of the present disclosure.

Referring to FIG. 4, in one or more aspects, the substrate 111 of the display panel 110 can include a display area AA configured to allow an image to be displayed and a non-display area NA in which an image is not displayed.

The non-display area NA can include a first non-display area NA1, a second non-display area NA2, a third non-display area NA3, and a fourth non-display area NA4.

The first non-display area NA1 can be disposed in a first direction from the display area AA. The second non-display area NA2 can be disposed in a second direction from the display area AA. The third non-display area NA3 can be disposed in a third direction from the display area AA. The fourth non-display area NA4 can be disposed in a fourth direction from the display area AA. But aspects of the present disclosure are not limited thereto.

For example, the first and third directions can be directions opposite to each other in the column direction. The second and fourth directions can be directions opposite to each other in the row direction. In another example, the first and third directions can be directions opposite to each other in the row direction. The second and fourth directions can be directions opposite to each other in the column direction. Hereinafter, for convenience of explanation, discussions can be provided based on examples where the first and third directions are directions opposite to each other in the column direction, and the second and fourth directions are directions opposite to each other in the row direction. But aspects of the present disclosure are not limited thereto.

For example, the column direction can be a direction in which data lines DL extend, and the row direction can be a direction in which gate lines GL extend. In another example, the column direction can be a direction in which gate lines GL extend, and the row direction can be a direction in which data line DL extend. Hereinafter, for convenience of explanation, discussions can be provided based on examples where the column direction is the direction in which data lines DL extend, and the row direction is the direction in which gate lines GL extend. However, aspects of the present disclosure are not limited thereto.

Referring to FIG. 4, the first non-display area NA1 can include a pad area PA. A plurality of pads to which at least one driving circuit or a printed circuit board is electrically connected can be disposed at the pad area PA. In one or more aspects, a plurality of data lines DL, a first common driving voltage line VDDL, and a second common driving voltage line VSSL can be electrically connected to the plurality of pads.

The first non-display area NA1 can further include a bending area BA. In this implementation, the substrate 111 can be a flexible substrate, but aspects of the present disclosure are not limited thereto. For example, the substrate 111 can be an inflexible substrate or can be a substrate having a flexible portion and an inflexible portion, or a combination thereof. In one or more aspects, the first non-display area NA1 need not include a bending area BA.

The display panel 110 can further include a ground line disposed in the non-display area NA of the substrate 111. The ground line can be disposed such that it runs from one point of the pad area PA to another point of the pad area PA via the second non-display area NA2, the third non-display area NA3, and the fourth non-display area NA4.

In one or more aspects, the encapsulation layer 200 disposed in the display panel 110 can have a structure in which at least one inorganic layer and at least one organic layer are stacked, but aspects of the present disclosure are not limited thereto. In these aspects, an edge of the encapsulation layer 200 can be an edge of an organic layer. The encapsulation layer 200 can extend from the display area AA to a portion of the non-display area NA.

In one or more aspects, to prevent overflow of an organic layer in the encapsulation layer 200, the display panel 110 can further include at least one dam or at least one stopper disposed outside of the organic layer included in the encapsulation layer 200. The at least one dam or the at least one stopper can include an organic layer, but aspects of the present disclosure are not limited thereto.

In the aspect of the present disclosure shown in FIG. 4, the display panel 110 is shown having a rectangular display area AA having a greater length in the vertical direction and a shorter length in the horizontal direction, but aspects of the present disclosure are not limited thereto, and a display panel having the greater length in the horizontal direction is within the scope of the present disclosure. Additionally, the display panel 110 need not be rectangular but can be a different shape, including oval, hexagonal or other polygons.

Additionally, although the non-display area NA is shown as having four non-display areas NA1, NA2, NA3 and NA4, one or more sides of the display panel 110 can be without a non-display area. Also, sizes, such as areas, widths and/or lengths of the non-display areas NA1, NA2, NA3 and/or NA4 can be different or the same.

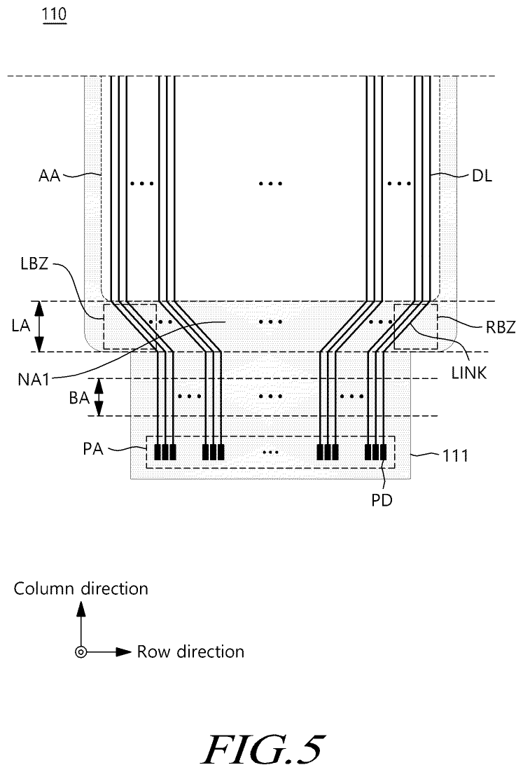

FIG. 5 is a plan view of the display panel 110 according to aspects of the present disclosure, and illustrates a data link structure configured in the display panel 110.

Referring to FIG. 5, in one or more aspects, the display panel 110 can include a plurality of data lines DL configured to deliver data voltages VDATA, and a plurality of pads PD disposed at the pad area PA and configured to allow the data driving circuit 120 to be electrically connected.

In one or more aspects, the display panel 110 can include a data link structure configured to electrically connect the plurality of data lines DL to the plurality of pads PD. In one or more aspects, the data link structure can include a plurality of data link lines LINK. The data link line can also be referred to as a link line.

A plurality of data link lines LINK can be disposed in the non-display area NA. For example, the plurality of data link lines LINK can be disposed in the first non-display area NA1 including the pad area PA.

The first non-display area NA1 can further include a link area LA in addition to the pad area PA and the bending area BA. But aspects of the present disclosure are not limited thereto.

For example, each of the plurality of data link lines LINK can be disposed across the pad area PA, the bending area BA, and the link area LA. Each of the plurality of data link lines LINK can include a first end (or a first side or a first portion) electrically connected to a pad PD disposed in the pad area PA, and a second end (or a second side or a second portion) electrically connected to a data line DL disposed in the display area AA. A portion between both ends (i.e., the first and second ends, or the first and second sides) of each of the plurality of data link lines LINK can be disposed across the bending area BA and the link area LA.

For example, each of the plurality of data link lines LINK can be configured with one line or two or more lines. Each of the plurality of data link lines LINK can be disposed in one metal layer or in two or more metal layers.

The bending area BA can be bent during the manufacturing process of the display panel 110. Accordingly, when a user views the display apparatus 100 in front thereof, the bending area BA and the pad area PA can be not visible to the user from the front.

However, when a user views the display apparatus 100 in front thereof, the link area LA can be recognized as a bezel even when it is covered by a case or cover member. Therefore, to implement a narrow bezel, it can be desirable to reduce the area or size of the link area LA.

Referring to FIG. 5, since all of a plurality of data link lines LINK in the link area LA of the first non-display area NA1 are required to be electrically connected to a plurality of data lines DL, the link area LA needs a large area.

For example, when a length of the pad area PA in the second direction (row direction) is shorter than a length of the display area AA in the second direction (row direction), each of a plurality of data link lines LINK in left and right areas (LBZ and RBZ) of the link area LA is needed to extend at a certain angle with respect to the row direction or the column direction and thereafter be electrically connected to a corresponding one of the plurality of data lines DL. This configuration leads the link area LA in the first direction (column direction) to have an increased length and the link area LA to have an increased area.

Accordingly, as shown in FIG. 5, in the example where the display panel 110 has a data link structure in which a plurality of data link lines LINK are disposed in the first non-display area NA1, the link area LA of the first non-display area NA1 can need a large area. In this implementation, when a user views the display apparatus 100 in front thereof, the link area LA can be recognized as a wide bezel.

Therefore, to implement a narrow bezel, it is required to provide a data link structure capable of reducing the area of the link area LA. Thus, a data link structure capable of implementing a narrow bezel is provided as discussed below.

Hereinafter, a data link structure capable of implementing a narrow bezel according to aspects of the present disclosure will be described.

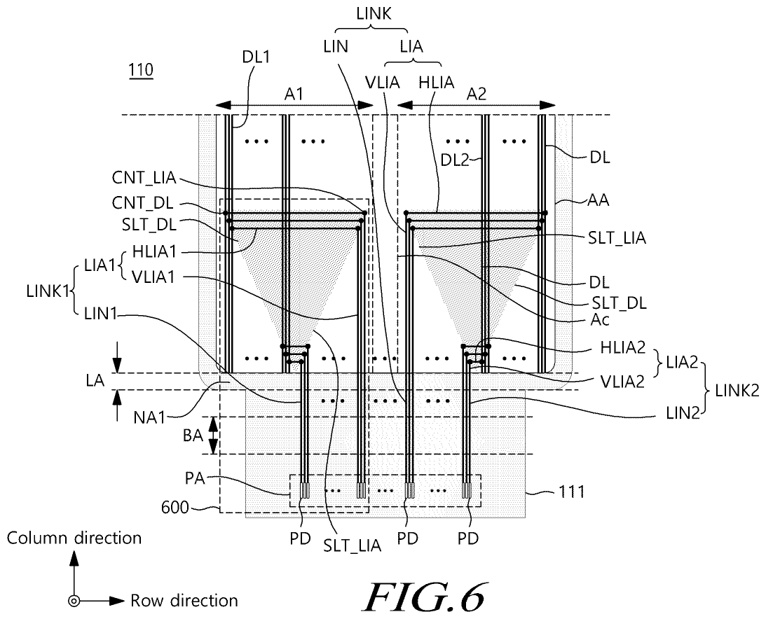

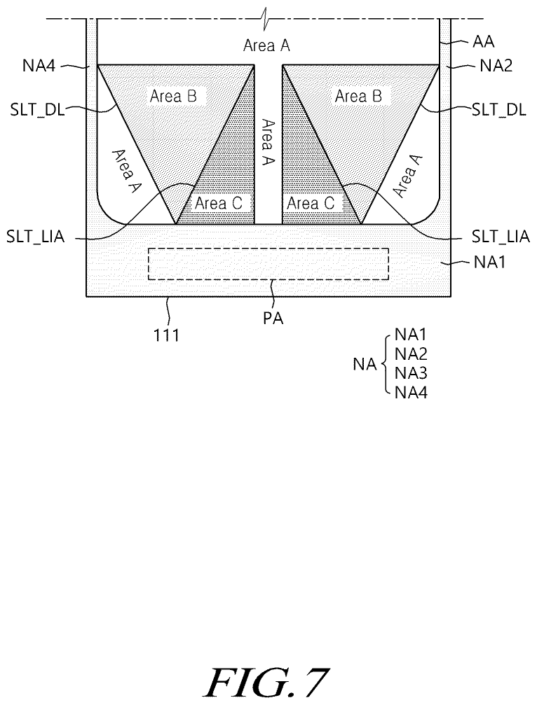

FIG. 6 is a plan view of the display panel 110 according to aspects of the present disclosure, and illustrates a data link structure capable reducing the bezel of the display panel 110 (“bezel reduction data link structure”). FIG. 7 illustrates three areas (A, B, and C areas) in the display area AA by the data link structure of the display panel 110 according to aspects of the present disclosure. A data link structure according to aspects described herein can be a bezel reduction data link structure.

Referring to FIG. 6, the non-display area NA can include a first non-display area NA1 disposed in the column direction from the display area AA. The first non-display area NA1 can include a pad area PA and a link area LA disposed in the column direction from the display area AA. But aspects of the present disclosure are not limited thereto.

In one or more aspects, the display panel 110 can include a data link structure capable of reducing the bezel of the display panel 110 and allowing (or suppling) data voltages VDATA to be supplied to a plurality of subpixels SP disposed in the display area AA.

Referring to FIG. 6, in one or more aspects, the bezel reduction data link structure can include a plurality of data link lines LINK configured to electrically connect a plurality of data lines DL to a plurality of pads PD.

The plurality of data lines DL can be disposed in the display area AA, extend in the column direction, and be connected to a plurality of subpixels SP disposed in the display area AA.

The plurality of pads PD can be disposed in the pad area PA included in the first non-display area NA1.

The plurality of data link lines LINK can electrically connect the plurality of pads PD disposed in the pad area PA of the first non-display area NA1 to the plurality of data lines DL disposed at the display area AA.

Referring to FIG. 6, in one or more aspects, each of the plurality of data link lines LINK in the data link structure for the narrow bezel can include a portion LIA disposed at the display area AA.

In the bezel reduction data link structure according to aspects of the present disclosure, the plurality of data link lines LINK and the plurality of data lines DL can be electrically connected to each other in the display area AA. For example, in the bezel reduction data link structure according to aspects of the present disclosure, connection points (or connection portions) CNT_DL between the plurality of data link lines LINK and the plurality of data lines DL can be disposed in the display area AA.

Accordingly, each of the plurality of data link lines LINK need not extend at a certain angle with respect to the row direction or the column direction (or diagonal direction or an oblique direction) in left and right areas of the link area LA, and each of the plurality of data link lines LINK can run the link area LA with a short length in the column direction, and enter the display area AA to be connected to a corresponding data line DL in the display area AA.

As shown in FIG. 6, in the example where the display panel 110 has the bezel reduction data link structure, the length of the link area LA in the column direction can be very short or be zero. Accordingly, the first non-display area NA1 viewed by a user in front of the display panel 110 can become very small, or be entirely absent so that the display area AA is directly connected to the bending area BA.

Referring to FIG. 6, in the bezel reduction data link structure according to aspects of the present disclosure, each of the plurality of data link lines LINK can include a data link line LIA of the display area AA or a data link line LIA in the display area AA (which can be referred to as a display area data link line LIA), which can be disposed in the display area AA.

The display area data link line LIA can be disposed in the display area AA, and include a horizontal data link line HLIA extending in the row direction (i.e., the horizontal direction), and a vertical data link line VLIA extending in the column direction (i.e., the vertical direction). The vertical data link line VLIA can be, for example, a first data link line or a first link line, but aspects of the present disclosure are not limited thereto. The horizontal data link line HLIA can be, for example, a second data link line or a second link line, but aspects of the present disclosure are not limited thereto.

The vertical data link line VLIA can electrically connect a corresponding pad PD to a corresponding horizontal data link line HLIA. The horizontal data link line HLIA can electrically connect a corresponding vertical data link line VLIA to a corresponding data line DL.

The horizontal data link line HLIA and the vertical data link line VLIA can be electrically connected to each other at a link line connection hole (or connection point or connection portion) CNT_LIA. The horizontal data link line HLIA and the data line DL can be electrically connected to each other at a data line connection hole (or connection point or connection portion) CNT_DL.

Referring to FIG. 6, each of the plurality of data link lines LINK can further include a data link line LIN of the non-display area NA or a data link line LIN in the non-display area NA (which can be referred to as a non-display area data link line LIN), which can be disposed in the first non-display area NA1 of the non-display area NA. But aspects of the present disclosure are not limited thereto.

For example, the non-display area data link line LIN and the vertical data link line VLIA can be integrally formed as a single line. In another example, the non-display area data link line LIN can be electrically connected to the vertical data link line VLIA, and be disposed in a different metal layer from a metal layer in which the vertical data link line VLIA is disposed. In another example, the non-display area data link line LIN can include a line electrically connected to the vertical data link line VLIA and disposed in a different metal layer from a metal layer in which the vertical data link line VLIA is disposed.

In the example where the display panel 110 has the bezel reduction data link structure as shown in FIG. 6, a horizontal data link line HLIA included in each of a plurality of data link lines LINK can be parallel to a plurality of gate lines GL disposed in the display area AA and extending in the row direction (the horizontal direction).

Further, in the example where the display panel 110 has the bezel reduction data link structure as shown in FIG. 6, the horizontal data link line HLIA included in each of the plurality of data link lines LINK can overlap with at least one gate line GL in the vertical direction (or in the vertical direction in the plan view).

Among the plurality of vertical data link lines VLIA, a vertical data link line VLIA electrically connected to a data line DL closer to the center (or at an inner portion) of the display area AA can have a length shorter than a vertical data link line VLIA electrically connected to a data line DL disposed further away from the center (or at an outer portion) of the display area AA. Among the plurality of vertical data link lines VLIA, a vertical data link line VLIA electrically connected to a data line DL further away from the center of the display area AA can have a length longer than a vertical data link line VLIA electrically connected to a data line DL disposed close to the center of the display area AA. Among the plurality of vertical data link lines VLIA, a vertical data link line VLIA electrically connected to a data line DL disposed closer to the center of the display area AA can have a length shorter than a vertical data link line VLIA electrically connected to a data line DL further away from the center of the display area AA.

Among a plurality of horizontal data link lines HLIA, a horizontal data link line HLIA electrically connected to a data line DL disposed closer to the center of the display area AA can have a relatively short length. Among the plurality of horizontal data link lines HLIA, a horizontal data link line HLIA electrically connected to a data line DL further away from the center of the display area AA can have a length longer than a horizontal data link line HLIA electrically connected to a data line DL disposed close to the center of the display area AA. Among the plurality of horizontal data link lines HLIA, a horizontal data link line HLIA electrically connected to a data line DL disposed closer to the center of the display area AA can have a length shorter than a horizontal data link line HLIA electrically connected to a data line DL further away from the center of the display area AA.

Among the plurality of horizontal data link lines HLIA, a horizontal data link line HLIA closer to the pad area PA can have a relatively short length. Among the plurality of horizontal data link lines HLIA, a horizontal data link line HLIA further away from the pad area PA can have a relatively long length. Among the plurality of horizontal data link lines HLIA, a horizontal data link line HLIA closer to the pad area PA can have a length shorter than a horizontal data link line HLIA further away from the pad area PA.

A first link line LINK1 can include a first display area data link line LIA1 (or a data link line LIA1 of a first display area or a data link line LIA1 in a first display area) and a first non-display area data link line LIN1 (or a data link line LIN1 of a first non-display area or a data link line LIN1 in a first non-display area). The first display area data link line LIA1 can include a first horizontal data link line HLIA1 and a first vertical data link line VLIA1. The first vertical data link line VLIA1 can be, for example, a 1-1^{st} data link line, a 1-1^{st} link line, a first data link line, or a first link line, but aspects of the present disclosure are not limited thereto. The first horizontal data link line HLIA1 can be, for example, a 2-1^{st} data link line, a 2-1^{st} link line, a seventh data link line, or a seventh link line, but aspects of the present disclosure are not limited thereto.

A second link line LINK2 can include a second display area data link line LIA2 (or a data link line LIA2 of a second display area or a data link line LIA2 in a second display area) and a second non-display area data link line LIN2 (or a data link line LIN2 of a second non-display area or a data link line LIN2 in a second non-display area). The second display area data link line LIA2 can include a second horizontal data link line HLIA2 and a second vertical data link line VLIA2. The second vertical data link line VLIA2 can be, for example, a 1-2^{nd} data link line, a 1-2^{nd} link line, a second data link line, or a second link line, but aspects of the present disclosure are not limited thereto. The second horizontal data link line HLIA2 can be, for example, a 2-2^{nd} data link line, a 2-2^{nd} link line, an eighth data link line, or an eighth link line, but aspects of the present disclosure are not limited thereto.

Among the first vertical data link line VLIA1 and the second vertical link line VLIA2, the first vertical data link line VLIA1 electrically connected, among a first data line DL1 and a second data line DL2, to the first data line DL1 disposed more outwardly relative to the second data line DL2 can have a length longer than the second vertical link line VLIA2.

Among the first horizontal data link line HLIA1 and the second horizontal data link line HLIA2, the first horizontal data link line HLIA1 electrically connected, among the first data line DL1 and the second data line DL2, to the first data line DL1 disposed more outwardly relative to the second data line DL2 can have a length longer than the second horizontal data link line HLIA2.

Since the first horizontal data link line HLIA1 has a length longer than the second horizontal data link line HLIA2, a first area where the first horizontal data link line HLIA1 overlaps with at least one gate line GL can be greater than a second area where the second horizontal data link line HLIA2 overlaps with at least one gate line GL.

As shown in FIG. 6, points (or portions) CNT_DL where data lines DL and horizontal data link lines HLIA are connected can form two first slant lines SLT_DL. Further, points (or portions) CNT_LIA where vertical data link lines VLIA and horizontal data link lines HLIA are connected can form two second slant lines SLT_LIA.

As shown in FIG. 6, two triangles can be formed by the two first slant lines SLT_DL and the two second slant lines SLT_LIA. In each of the two triangles, one of three sides can be a horizontal side parallel to the horizontal data link lines HLIA, and a vertex facing this horizontal side can be disposed in a boundary between the display area AA and the first non-display area NA1 or be disposed at near the boundary.

Referring to FIG. 6, the display area AA can include a central area Ac, a first area A1 on one side of the central area Ac, and a second area A2 on the other side of the central area Ac.

Referring to FIG. 6, data lines DL disposed in the first area A1 and the second area A2 can be connected to non-display area data link lines LIN through display area data link lines LIA.

In an aspect, at least one data line DL disposed in the central area Ac can be directly connected to a corresponding non-display area data link line LIN without going through a display area link line LIA.

In the example where the display panel 110 has the data link structure as shown in FIG. 6, respective horizontal data link lines HLIA in a plurality of data link lines LINK can be parallel to a plurality of gate lines GL disposed in the display area AA and extending in the row direction (the horizontal direction), and respective horizontal data link lines HLIA included in the plurality of data link lines LINK can overlap with at least one gate line GL in the vertical direction (or in the vertical direction in the plan view).

Referring to FIG. 7, according to a data link structure capable of reducing the bezel of the display panel 110, the display area AA can include three areas (A, B, and C).

A first area (Area A) can be an area in which a bezel reduction data link structure is not configured. A second area (Area B) and a third area (Area C) can be areas where a bezel reduction data link structure (e.g., the bezel reduction data link structure described above) is configured. The second area (Area B) can be an area where horizontal data link lines HLIA are disposed. The third area (Area C) can be an area where vertical data link lines VLIA are disposed.

Among the first to fourth non-display areas (NA1 to NA4) included in the non-display area NA, the first non-display area NA1 including the pad area PA can adjoin one side of each third area (Area C).

The second area (Area B) can have an inverted triangle shape or an isosceles triangle shape, but aspects of the present disclosure are not limited thereto. The display area AA can include two second areas (Area B). The two second areas (Area B) can be respectively disposed on both sides of the first area (Area A) located in a central portion of the display area AA.

The third area (Area C) can have a right triangle shape, but aspects of the present disclosure are not limited thereto. The display area AA can include two third areas (Area C). The two third areas (Area C) can be respectively located on both sides of the first area (Area A) disposed in the central portion of the display area AA.

The first area (Area A) can be disposed on (or at the top of or an upper portion) the two second areas (Area B), also be disposed between the two third areas (Area C), and/or also be disposed outside of the two second areas (Area B). The first area (Area A) located between the two third areas (Area C) can correspond to the central area Ac of FIG. 6.

Referring to FIGS. 6 and 7, a boundary between the first area (Area A) and each of the two second areas (Area B) can correspond to points (or portions) CNT_DL where horizontal data link lines HLIA and data lines DL are connected, and form a first slant line SLT_DL.

A boundary between second area (Area B) and third area (Area C) can correspond to points (or portions) CNT_LIA where vertical data link lines VLIA and horizontal data link lines HLIA are connected, and form a second slant line SLT_LIA.

In various aspects of the present disclosure, each Area A (on the left and right sides) can have the same area, each Area B can have the same area, and each Area C can have the same area, but such is not required. Thus, each Area A (on the left and right sides) can also have different areas, each Area B can have different areas, and each Area C can have different areas.

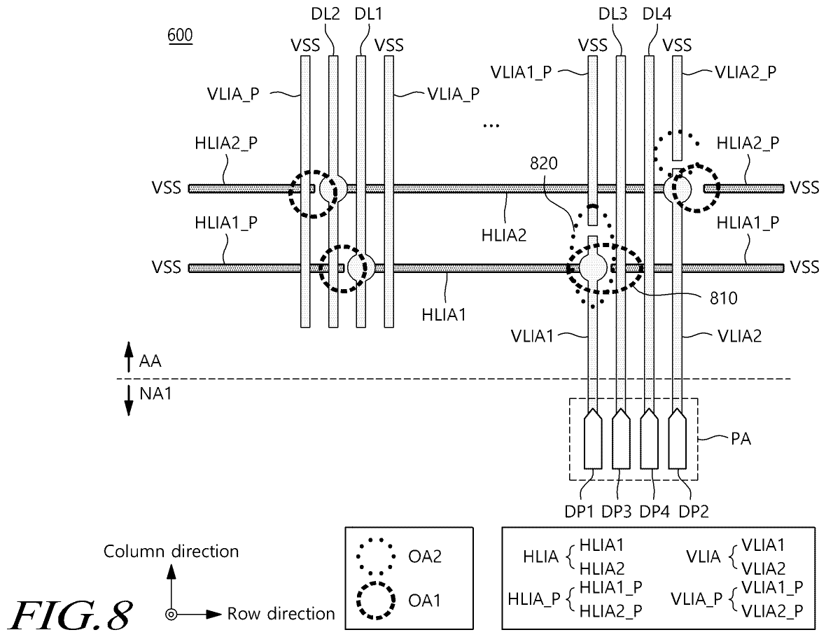

FIG. 8 illustrates an area of the display panel 110 with a data link structure according to aspects of the present disclosure. The configuration of FIG. 8 is discussed below along with the FIG. 6.

Referring to FIGS. 8 and 6, the first non-display area NA1 can include a pad area PA where a plurality of data pads (DP1, DP2, DP3, and/or DP4) are disposed. The plurality of data pads (DP1, DP2, DP3, and/or DP4) can include a first data pad DP1, a second data pad DP2, a third data pad DP3, and a fourth data pad DP4.

A plurality of data lines DL can be disposed in the display area AA, and include a first data line DL1, a second data line DL2, a third data line DL3, and a fourth data line DL4. Each of the first data line DL1, the second data line DL2, the third data line DL3, and the fourth data line DL4 can be disposed in the display area AA, and extend in the column direction. A corresponding data voltage can be applied to each of the first data line DL1, the second data line DL2, the third data line DL3, and the fourth data line DL4.

Referring to FIGS. 8 and 6, a data link structure (e.g., the bezel reduction data link structure discussed above) can be configured in a portion of the display area AA adjacent to the first non-display area NA1. Thus, the bezel reduction data link structure discussed with reference to FIG. 6 can be configured for the data link structure of FIG. 8.

The data link structure can include display area data link lines LIA. The display area data link lines LIA can include horizontal data link lines HLIA and vertical data link lines VLIA.

Each of the horizontal data link lines HLIA can be disposed in the display area AA. All or at least part of each of the vertical data link lines VLIA can be disposed in the display area AA.

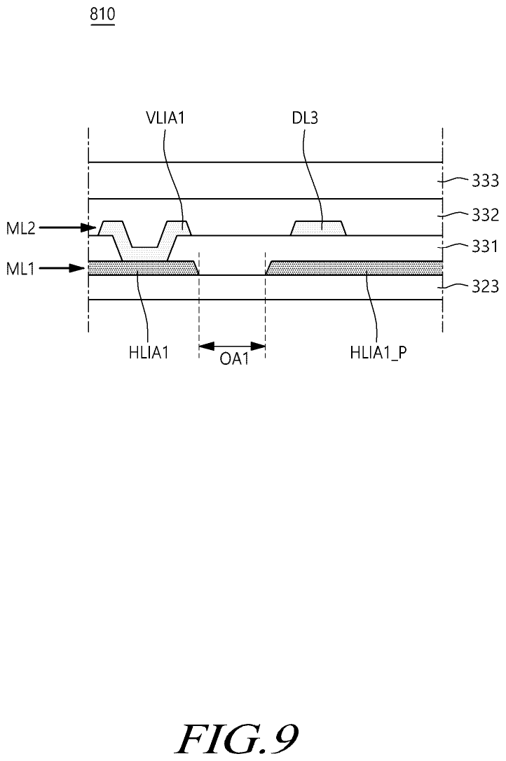

Referring to FIG. 8, horizontal data link lines HLIA can be electrically connected to data lines including the first data line DL1. The horizontal data link lines HLIA can be disposed in the display area AA. The horizontal data link lines HLIA can extend in the row direction. The horizontal data link lines HLIA can include a first horizontal data link line HLIA1 disposed in a first metal layer ML1 (see FIG. 9).

At least one vertical data link line VLIA can electrically connect the first horizontal data link line HLIA1 to the first data pad DP1. Vertical data link lines VLIA can extend in the column direction. The vertical data link lines VLIA can include a first vertical data link line VLIA1 disposed in a second metal layer ML2 different from the first metal layer ML1. All or at least part of the first vertical data link line VLIA1 can be disposed in the display area AA.

At least one horizontal data link lines HLIA can be electrically connected to the second data line DL2. The horizontal data link lines HLIA can be disposed in the display area AA. The horizontal data link lines HLIA can extend in the row direction. The horizontal data link lines HLIA can further include a second horizontal data link line HLIA2 disposed in the first metal layer ML1.

At least one vertical data link line VLIA can electrically connect the second horizontal data link line HLIA2 to the second data pad DP2. The vertical data link lines VLIA can extend in the column direction. The vertical data link lines VLIA can further include a second vertical data link line VLIA2 disposed in the second metal layer ML2 different from the first metal layer ML1. All or at least part of the second vertical data link line VLIA2 can be disposed in the display area AA. But aspects of the present disclosure are not limited thereto.

Referring to FIG. 8, in one or more aspects, the display panel 600 can include at least one horizontal metal layer HLIA_P and at least one vertical metal layer VLIA_P. A horizontal metal layer HLIA_P can be spaced apart from a horizontal data link line HLIA, extend in the row direction, and can be disposed in the first metal layer ML1. A vertical metal layer VLIA_P can be spaced apart from a vertical data link line VLIA, extend in the column direction, and be disposed in the second metal layer ML2.

The at least one horizontal metal layer HLIA_P can include a first horizontal metal layer HLIA1_P. The first horizontal metal layer HLIA1_P can be spaced apart from the first horizontal data link line HLIA, extend in the row direction, and can be disposed in the first metal layer ML1.

The at least one horizontal metal layer HLIA_P can include a second horizontal metal layer HLIA2_P. The second horizontal metal layer HLIA2_P can be spaced apart from the second horizontal data link line HLIA2, extend in the row direction, and can be disposed in the first metal layer ML1.

The at least one vertical metal layer VLIA_P can include a first vertical metal layer VLIA1_P. The first vertical metal layer VLIA1_P can be spaced apart from the first vertical data link line VLIA1, extend in the column direction, and can be disposed in the second metal layer ML2.

The at least one vertical metal layer VLIA_P can include a second vertical metal layer VLIA2_P. The second vertical metal layer VLIA2_P can be spaced apart from the second vertical data link line VLIA2, extend in the column direction, and can be disposed in the second metal layer ML2.

In a situation where the first and second horizontal metal layers (HLIA1_P and HLIA2_P) are not disposed in an area where the first and second horizontal metal layers (HLIA1_P and HLIA2_P) are disposed, an unbalance in the presence of the first metal layer can occur between an area where the first and second horizontal metal layers (HLIA1_P and HLIA2_P) are disposed and an area where the first and second horizontal metal layers (HLIA1_P and HLIA2_P) are not disposed. Due to such a configuration, respective characteristics of reflecting light in each location inside of the display panel 110 can become significantly different, this leading to display artifacts such as image abnormalities, luminance differences, color differences, and the like. The light can include at least a part of an amount of internal light emitted from one or more light emitting elements ED and an amount of external light introduced into the display panel 110 from the outside.

In a situation where the first and second vertical metal layers (VLIA1_P and VLIA2_P) are not disposed in an area where the first and second vertical metal layers (VLIA1_P and VLIA2_P) are disposed, an unbalance in the presence of the second metal layer can occur between an area where the first and second vertical metal layers (VLIA1_P and VLIA2_P) are disposed and an area where the first and second vertical metal layers (VLIA1_P and VLIA2_P) are not disposed. Due to such a configuration, respective characteristics of reflecting light in each location inside of the display panel 110 can become significantly different, this leading to display artifacts such as image abnormalities, luminance differences, color differences, and the like. But aspects of the present disclosure are not limited thereto.

For example, display artifacts due to such an unbalance in the presence of one or more metal layers can be reduced by disposing the first and second horizontal metal layers (HLIA1_P and HLIA2_P) and the first and second vertical metal layers (VLIA1_P and VLIA2_P).

A common driving voltage carried by at least one horizontal metal layer HLIA_P and at least one vertical metal layer VLIA_P can be one of the first common driving voltage VDD and the second common driving voltage VSS illustrated in FIG. 2. However, the common driving voltage carried by at least one horizontal metal layer HLIA_P and at least one vertical metal layer VLIA_P is not limited to the first common driving voltage VDD and the second common driving voltage VSS, and can be any one of DC voltages supplied to the display panel 110.

Herein, for convenience of description, discussions are provided based on examples where the common driving voltage carried by at least one horizontal metal layer HLIA_P and at least one vertical metal layer VLIA_P is the second common driving voltage VSS. The second common driving voltage VSS can be also referred to as a base voltage or a low power supply voltage.

Referring to FIG. 8, horizontal metal layers HLIA_P and vertical metal layers VLIA_P can be configured in a mesh pattern (or a mesh shape). By applying this configuration, an area through which the base voltage VSS, which is the second common driving voltage, is supplied can be significantly increased by at least one horizontal metal layer HLIA_P and at least one vertical metal layer VLIA_P. Thereby, the transfer characteristics of the base voltage VSS can also be significantly improved.

In addition, the length and area of paths through which data voltages are transmitted can be reduced, because the first horizontal data link line HLIA1 and the first horizontal metal layer HLIA1_P extending in the same direction are spaced apart from each other, the first vertical data link line VLIA1 and the first vertical metal layer VLIA1_P extending in the same direction are spaced apart from each other, the second horizontal data link line HLIA2 and the second horizontal metal layer HLIA2_P extending in the same direction are spaced apart from each other, and the second vertical data link line VLIA2 and the second vertical metal layer VLIA2_P extending in the same direction are spaced apart from each other. By applying this configuration, parasitic capacitance related to the first and second data lines DL1 and DL2 can be reduced.

The horizontal metal layers HLIA_P and the vertical metal layers VLIA_P can be lines configured to carry (or transfer) a common driving voltage configured to drive the display panel.

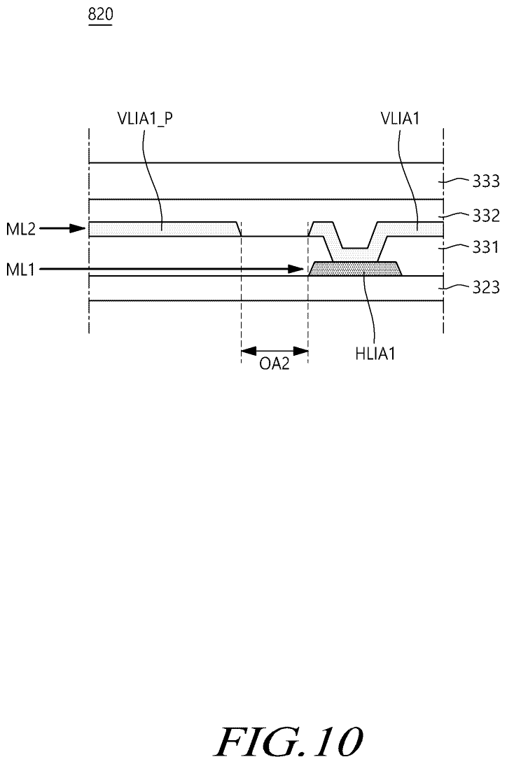

FIGS. 9 and 10 are cross-sectional views of the display panel 810 and 820 respectively having a data link structure capable of reducing the bezel according to aspects of the present disclosure. The configurations of FIGS. 9 and 10 are discussed below along with the configurations of FIGS. 6 and 8.

Referring to FIG. 9, the first horizontal data link line HLIA1 and the first horizontal metal layer HLIA1_P can be disposed on a second interlayer insulating layer 323 (e.g., the second interlayer insulating layer 323 of FIG. 3). The first horizontal data link line HLIA1 and the first horizontal metal layer HLIA1_P can be disposed such that they are spaced apart from each other. But aspects of the present disclosure are not limited thereto.

A first planarization layer 331 (e.g., the first planarization layer 331 of FIG. 3) can be disposed on the first horizontal data link line HLIA1 and the first horizontal metal layer HLIA1_P.

The first vertical data link line VLIA1 and a vertical line (e.g., the data line DL3 discussed above) can be disposed on the first planarization layer 331.

The first vertical data link line VLIA1 can be connected to the first horizontal data link line HLIA1 through a hole of the first planarization layer 331.

A second planarization layer 332 (e.g., the second planarization layer 332 of FIG. 3) can be disposed on the first vertical data link line VLIA1 and the vertical line (e.g., the data line DL3). A bank 333 (e.g., the bank 333 of FIG. 3) can be disposed on the second planarization layer 332.

A metal layer in which the first horizontal data link line HLIA1 and the first horizontal metal layer HLIA1_P are disposed can be a first metal layer ML1 between the second interlayer insulating layer 323 and the first planarization layer 331.

A space (or a distance) between the first horizontal data link line HLIA1 and the first horizontal metal layer HLIA1_P in the first metal layer ML1 can be referred to as a first open area OA1 of the first metal layer ML1.

A metal layer in which the first vertical data link line VLIA1 and the vertical line (e.g., the data line DL3) are disposed can be a second metal layer ML2 between the first planarization layer 331 and the second planarization layer 332.

Referring to FIG. 10, the first horizontal data link line HLIA1 can be disposed on the second interlayer insulating layer 323.

The first planarization layer 331 can be disposed on the first horizontal data link line HLIA1.

The first vertical data link line VLIA1 and the first vertical metal layer VLIA1_P can be disposed on the first planarization layer 331 such that the first vertical data link line VLIA1 and the first vertical metal layer VLIA1_P can be spaced apart from each other.

The first vertical data link line VLIA1 can be connected to the first horizontal data link line HLIA1 through a hole of the first planarization layer 331.

The second planarization layer 332 can be disposed on the first vertical data link line VLIA1 and the first vertical metal layer VLIA1_P. The bank 333 can be disposed on the second planarization layer 332.

Both the first vertical metal layer VLIA1_P and the first vertical data link line VLIA1 can be disposed in the second metal layer ML2.

A space (or a distance) between the first vertical metal layer VLIA1_P and the first vertical data link line VLIA1 in the second metal layer ML2 can be referred to as a second open area OA2 of the second metal layer ML2.

As described above, a common driving voltage needed for display panel driving can be supplied through the horizontal metal layers (HLIA1_P, HLIA2_P) spaced apart from the horizontal data link lines (HLIA1, HLIA2) and the vertical metal layers (VLIA1_P, VLIA2_P) spaced apart from the vertical data link lines (VLIA1, VLIA2). For example, the common driving voltage can be the base voltage VSS.

Accordingly, paths through which the common driving voltage is transmitted can be configured in a mesh pattern (or a mesh shape). Thus, an area across which the common driving voltage is transferred increases, and the transfer characteristics of the common driving voltage can also be greatly improved. But aspects of the present disclosure are not limited thereto.

In FIGS. 9 and 10, the locations of the first metal layer ML1 and the second metal layer ML2 can be switched. For example, the first metal layer ML1 may be on the second metal layer ML2.

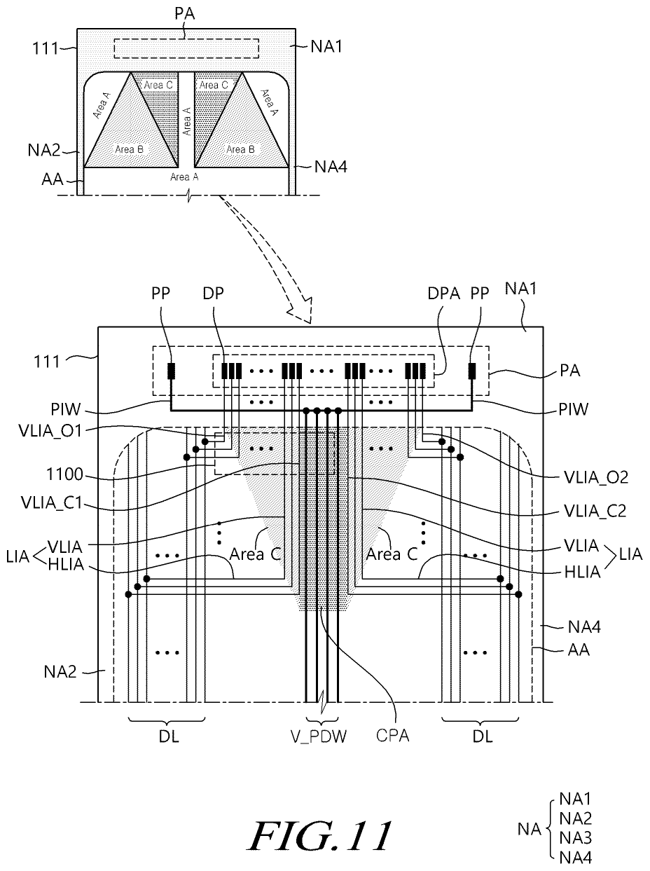

Hereinafter, a structure of power lines through which the common driving voltage is transferred is described in more detail with reference to FIGS. 11 to 16.

FIG. 11 is a plan view of the display panel 110 according to aspects of the present disclosure having a power line structure associated with the bezel reduction data link structure.

Referring to FIGS. 11 and 3, in one or more aspects, the display panel 110 can include the substrate 111, a plurality of data lines DL, and the like.

The substrate 111 can include the display area AA including a plurality of subpixels SP and a non-display area NA disposed outside of the display area AA. The non-display area NA can include a pad area PA.

Referring to FIGS. 11 and 4, the non-display area NA can include the first non-display area NA1, the second non-display area NA2, the third non-display area NA3, and the fourth non-display area NA4. The first non-display area NA1 can include the pad area PA.

The pad area PA can include a data pad area DPA where a plurality of data pads DP are disposed.

A plurality of data lines DL can extend in the column direction in the display area AA. For example, one or more of the plurality of data lines DL can be connected to one or more of the plurality of data pads DP disposed in the pad area PA and extend to the display area AA. Further, other one or more of the plurality of data lines DL can be disposed only in the display area AA.

In one or more aspects, the display panel 110 can include a data link structure. The data link structure can include a plurality of display area data link lines LIA. The plurality of display area data link lines LIA can be disposed in the second area (Area B) and the third area (Area C) among the first to third areas (A, B, and C) of FIG. 7. The data link structure configured in the FIG. 11 can be based on the bezel reduction data link structure discussed above.

The plurality of display area data link lines LIA can include a plurality of vertical data link lines VLIA and a plurality of horizontal data link lines HLIA. The plurality of vertical data link lines VLIA and the plurality of horizontal data link lines HLIA can be disposed in the display area AA. The plurality of vertical data link lines VLIA can be electrically connected to a plurality of data pads DP and can extend in the column direction in the display area AA. The plurality of horizontal data link lines HLIA can electrically connect the plurality of vertical data link lines VLIA to a plurality of data lines DL, and can extend in the row direction in the display area AA.

The plurality of vertical data link lines VLIA can be disposed in two third areas (Area C). The plurality of horizontal data link lines HLIA can be disposed in two second areas (Area B). A portion of the first area (Area A) can be present between the two third areas (Area C). But aspects of the present disclosure are not limited thereto.

Referring to FIG. 11, in one or more aspects, the display panel 110 can include the bezel reduction data link structure and a power line structure associated therewith.

In one or more aspects, the power line structure of the display panel 110 can include at least one power pad PP, at least one power supply line PIW, and a plurality of vertical power distribution lines V_PDW. The at least one power pad PP can be disposed in the pad area PA. The power supply line PIW can be electrically connected to the at least one power pad PP and can be disposed in the non-display area NA. The plurality of vertical power distribution lines V_PDW can be electrically connected to the power supply line PIW and can extend in the column direction in the display area AA. The power supply line PIW can be a power supply line disposed in an edge area (or a periphery area) of the display panel 110, but aspects of the present disclosure are not limited thereto. The plurality of vertical power distribution lines V_PDW can be a plurality of first power distribution lines or a plurality of first power lines, but aspects of the present disclosure are not limited thereto.

As shown in FIG. 11, the non-display area NA can include the pad area PA including the plurality of data pads DP and the at least one power pad PP. For example, at least one power pad PP can be disposed on each of one side and the other side of a data pad area DPA in which the plurality of data pads DP are disposed. In another example, at least one power pad PP can be disposed at one side, or the other side, of the data pad area DPA.

The power supply line PIW can be disposed in the first non-display area NA1. The power supply line PIW can be disposed in an area between the pad area PA and the display area AA.

In one or more aspects, at least one additional power supply line PIW can be disposed in at least one of the second non-display area NA2 and the third non-display area NA3. In one or more aspects, at least one additional power supply line PIW can be disposed in at least one of the second non-display area NA2 and the third non-display area NA3, and the fourth non-display area NA4.

Referring to FIG. 11, each of the plurality of vertical power distribution lines V_PDW can be connected to the power supply line PIW and extend into the display area AA. Each of the plurality of vertical power distribution lines V_PDW can extend in the column direction in the display area AA. For example, at least one of the plurality of vertical power distribution lines V_PDW can be a first power distribution line or a first power line, but aspects of the present disclosure are not limited thereto.

In one or more aspects, the power line structure of the display panel 110 can be configured to supply a common driving voltage configured to drive the display panel to a plurality of subpixels SP disposed in the display area AA. But aspects of the present disclosure are not limited thereto.

For example, a common driving voltage supplied by the power line structure of the display panel 110 can be one of the first common driving voltage VDD and the second common driving voltage VSS illustrated in FIG. 2. However, the common driving voltage supplied by the power line structure of the display panel 110 is not limited to the first common driving voltage VDD and the second common driving voltage VSS, and can be any one of DC voltages supplied to the display panel 110.

Referring to FIG. 11, in one or more aspects, the plurality of vertical data link lines VLIA can include a first central vertical data link line VLIA_C1 and a second central vertical data link line VLIA_C2, which are disposed at a central portion of an area where the plurality of vertical data link lines VLIA are disposed, and a first outmost vertical data link line VLIA_O1 and a second outmost vertical data link line VLIA_O2, which are disposed at both outmost side portions of the area where the plurality of vertical data link lines VLIA are disposed. The first central vertical data link line VLIA_C1 can be, for example, a 1-3^{rd} data link line, a 1-3^{rd} link line, a third data link line, or a third link line, but aspects of the present disclosure are not limited thereto. The second central vertical data link line VLIA_C2 can be, for example, a 1-4^{th} data link line, a 1-4^{th} link line, a fourth data link line, or a fourth link line, but aspects of the present disclosure not limited thereto. The first outmost vertical data link line VLIA_O1 can be, for example, a 1-5^{th} data link line, a 1-5^{th} link line, a fifth data link line, or a fifth link line, but aspects of the present disclosure not limited thereto. The second outmost vertical data link line VLIA_O2 can be, for example, a 1-6^{th} data link line, a 1-6^{th} link line, a sixth data link line, or a sixth link line, but aspects of the present disclosure not limited thereto.

The first central vertical data link line VLIA_C1 can have a length longer than the first outmost vertical data link line VLIA_O1.

The second central vertical data link line VLIA_C2 can have a length longer than the second outmost vertical data link line VLIA_O2.

Referring to FIG. 11, in one or more aspects, a horizontal data link line HLIA connected to the first central vertical data link line VLIA_C1 can have a length longer than a horizontal data link line HLIA connected to the first outmost vertical data link line VLIA_O1.

A horizontal data link line HLIA connected to the second central vertical data link line VLIA_C2 can have a length longer than a horizontal data link line HLIA connected to the second outmost vertical data link line VLIA_O2.

The plurality of horizontal data link lines HLIA can be disposed in a first metal layer ML1 (e.g., the first metal layer ML1 shown in FIGS. 9 and 10). The plurality of vertical data link lines VLIA can be disposed in a second metal layer ML2 (e.g., the second metal layer ML1 shown in FIGS. 9 and 10) different from the first metal layer ML1.

A plurality of data lines DL can be disposed in the second metal layer ML2.

As described above, horizontal lines extending in the row direction can be disposed in the first metal layer ML1, and vertical lines extending in the column direction can be disposed in the second metal layer ML2.

Each of the plurality of vertical power distribution lines V_PDW can have a length longer than each of the plurality of vertical data link lines VLIA. But aspects of the present disclosure are not limited thereto.

For example, each of a plurality of vertical power link lines (or vertical metal layers) VLIA_P can have a length greater than the longest vertical data link lines (VLIA_C1 and VLIA_C2) among the plurality of vertical data link lines VLIA.

Referring to FIG. 11, the plurality of vertical data link lines VLIA can include the first central vertical data link line VLIA_C1 and the second central vertical data link line VLIA_C2, which are disposed at the central portion of the area where the plurality of vertical data link lines VLIA are disposed.

The plurality of vertical power distribution lines V_PDW can be disposed between the first central vertical data link line VLIA_C1 and the second central vertical data link line VLIA_C2.

Referring to FIGS. 11 and 7, the display area AA can include the first area (Area A) in which a plurality of vertical data link lines VLIA and a plurality of horizontal data link lines HLIA are not disposed, the two second areas (Area B) in which a plurality of horizontal data link lines HLIA are disposed, and the two third areas (Area C) where a plurality of vertical data link lines VLIA are disposed.

Referring to FIGS. 11 and 7, an area between the two third areas (Area C) can correspond to a portion of the first area (Area A). The plurality of vertical power distribution lines V_PDW can be disposed in a central power area CPA, which can be the first area (Area A) between the two third areas (Area C).

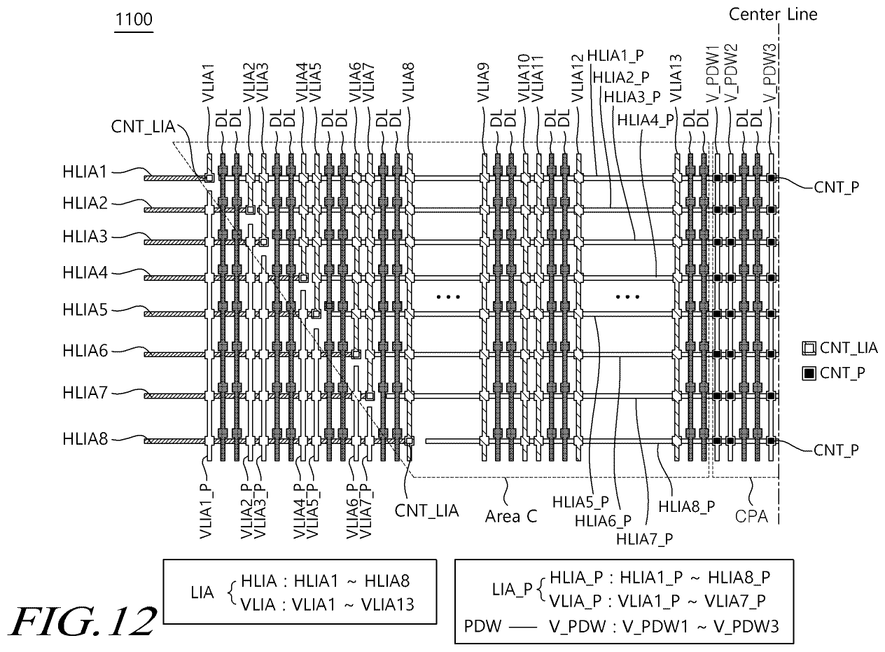

FIG. 12 is a plan view of a partial area 1100 in the configuration of FIG. 11. Discussions on the configuration of FIG. 12 along with the configuration of FIG. 11 are provided below.

Referring to FIG. 12, in one or more aspects, a data link structure of the display panel 110 can include a plurality of display area data link lines LIA including a plurality of horizontal data link lines HLIA and a plurality of vertical data link lines VLIA. A horizontal data link line HLIA and a vertical data link line VLIA, which are disposed to correspond to each other, can be electrically connected through a link line connection hole CNT_LIA. But aspects of the present disclosure are not limited thereto.

For example, the plurality of horizontal data link lines HLIA can include first to eighth horizontal data link lines (HLIA1 to HLIA8), and the plurality of vertical data link lines VLIA can include first to thirteenth vertical data link lines (VLIA1 to VLIA13). This example is merely for convenience of explanation, therefore, aspects of the present disclosure are not limited thereto.

Referring to FIG. 12, the first vertical data link line VLIA1 can correspond to the first outermost vertical data link line VLIA_O1 of FIG. 11. The thirteenth vertical data link line VLIA13 can correspond to the first central vertical data link line VLIA_C1 of FIG. 11.

In one or more aspects, a power line structure of the display panel 110 can include at least one power distribution line PDW for distributing a common driving voltage to the display area AA.

The at least one power distribution line PDW can be electrically connected to a power supply line PIW (e.g., the power supply line PIW of FIG. 11). The at least one power distribution line PDW can include a plurality of vertical power distribution lines V_PDW (e.g., the vertical power distribution lines V_PDW of FIG. 11) extending in the column direction in the display area AA. For example, the vertical power distribution line V_PDW can be a first power distribution line or a first power line, but aspects of the present disclosure are not limited thereto.

For example, the plurality of vertical power distribution lines V_PDW can include a first vertical power distribution line V_PDW1, a second vertical power distribution line V_PDW2, and a third vertical power distribution line V_PDW3. This example is merely for convenience of explanation, therefore, aspects of the present disclosure are not limited thereto.

Referring to FIG. 12, the plurality of vertical power distribution lines V_PDW can be disposed in the central power area CPA, which can be the first area (Area A) between the two third areas (Area C).

In one or more aspects, the power line structure of the display panel 110 can include a plurality of power link lines LIA_P configured to transfer a common driving voltage distributed from the vertical power distribution lines V_PDW to a plurality of subpixels SP.

The plurality of power link lines LIA_P can include a plurality of horizontal power link lines HLIA_P and a plurality of vertical power link lines VLIA_P. For example, one of the vertical power link lines VLIA_P can be a first power link line or a ninth link line, but aspects of the present disclosure are not limited thereto. For example, one of the horizontal power link lines VLIA_P can be a second power link line or a second link line, but aspects of the present disclosure are not limited thereto.

Each of the plurality of horizontal power link lines HLIA_P can be electrically connected to a corresponding one of the plurality of vertical power distribution lines V_PDW through power line connection holes CNT_P and can extend in the row direction in the display area AA.

The plurality of vertical power link lines VLIA_P can be electrically connected to the plurality of vertical power distribution lines V_PDW or an extension power supply line and can extend in the column direction in the display area AA. For example, the extension power supply line PIW can be a line extending from a power supply line PIW of the first non-display area NA1 to the second to fourth non-display areas (NA2, NA3, and/or NA4). But aspects of the present disclosure are not limited thereto.

For example, the plurality of horizontal power link lines HLIA_P can include first to eighth horizontal power link lines (HLIA1_P to HLIA8_P). This example is merely for convenience of explanation; therefore, aspects of the present disclosure are not limited thereto.

For example, the plurality of vertical power link lines VLIA_P can include first to seventh vertical power link lines (VLIA1_P to VLIA7_P). This example is merely for convenience of explanation, therefore, aspects of the present disclosure are not limited thereto.

The plurality of horizontal power link lines HLIA_P of FIG. 12 can correspond to the horizontal metal layers HLIA_P of FIG. 8, and the plurality of vertical power link lines VLIA_P of FIG. 12 can correspond to the vertical metal layers VLIA_P of FIG. 8.

Referring to FIG. 12, the plurality of horizontal power link lines HLIA_P can correspond to a plurality of horizontal data link lines HLIA, respectively. The plurality of vertical power link lines VLIA_P can correspond to a plurality of vertical data link lines VLIA, respectively.

For example, the plurality of horizontal data link lines HLIA can include a first horizontal data link line HLIA1 and a second horizontal data link line HLIA2 disposed further away from the pad area PA than the first horizontal data link line HLIA1.

The plurality of horizontal power link lines HLIA_P can include the first horizontal power link line HLIA1_P and the second horizontal power link line HLIA2_P. The first horizontal power link line HLIA1_P can be disposed in the same first row as the first horizontal data link line HLIA1 and can be spaced apart from the first horizontal data link line HLIA1. The second horizontal power link line HLIA2_P can be disposed in the same second row as the second horizontal data link line HLIA2 and can be spaced apart from the second horizontal data link line HLIA2. The first horizontal power link line HLIA1_P can be, for example, a 2-1^{st} power link line, a second power link line, or a tenth link line, but aspects of the present disclosure are not limited thereto. The second horizontal power link line HLIA2_P can be, for example, a 2-2^{nd} power link line, a third power link line, or an eleventh link line, but aspects of the present disclosure are not limited thereto.

Referring to FIG. 12, the second horizontal data link line HLIA2 can have a length longer than the first horizontal data link line HLIA1.

The second horizontal power link line HLIA2_P can have a length longer than the first horizontal power link line HLIA1_P.

Hereinafter, a configuration relationship between the data link structure and the power line structure will be described in more detail.

Referring to FIG. 12, an n^{th} horizontal data link line HLIAn (where n=1, 2, . . . ) among a plurality of horizontal data link lines HLIA can correspond to an n^{th} horizontal power link line HLIAn_P (where n=1, 2, . . . ) among a plurality of horizontal power link lines HLIA_P.

The n^{th} horizontal data link line HLIAn (where n=1, 2, . . . ) and the n^{th} horizontal power link line HLIAn_P (where n=1, 2, . . . ) can be disposed to be spaced apart from each other in a same n^{th} row.

An m^{th} vertical data link line VLIAm (where m=1, 2, . . . ) among a plurality of vertical data link lines VLIA can correspond to an m^{th} vertical power link line VLIAm_P (where m=1, 2, . . . ) among a plurality of vertical power link lines VLIA_P.

The m^{th} vertical data link line VLIAm (where m=1, 2, . . . ) and the m^{th} vertical power link line VLIAm_P (where m=1, 2, . . . ) can be disposed to be spaced apart from each other in a same m^{th} column.

An i^{th} horizontal data link line HLIAi (where i=1, 2, . . . ) among the plurality of horizontal data link lines HLIA can correspond to an i^{th} horizontal power link line HLIAi_P (where i=1, 2, . . . ) among the plurality of horizontal power link lines HLIA_P. Here, i can be a natural number different from n.

The i^{th} horizontal data link line HLIAi (where i=1, 2, . . . ) and the i^{th} horizontal power link line HLIAi_P (where i=1, 2, . . . ) can be disposed to be spaced apart from each other in an i^{th} row different from the n^{th} row.

A j^{th} vertical data link line VLIAj (where j=1, 2, . . . ) among the plurality of vertical data link lines VLIA can correspond to a j^{th} vertical power link line VLIAj_P (where j=1, 2, . . . ) among the plurality of vertical power link lines VLIA_P. Here, j can be a natural number different from m.

The j^{th} vertical data link line VLIAj (where j=1, 2, . . . ) and the j^{th} vertical power link line VLIAj_P (where j=1, 2, . . . ) can be disposed to be spaced apart from each other in a j^{th} column different from the m^{th} column.

The sum of respective lengths of the n^{th} horizontal data link line HLIAn and the n^{th} horizontal power link line HLIAn_P can correspond to the sum of respective lengths of the i^{th} horizontal data link line HLIAi and the i^{th} horizontal power link line HLIAi_P.

The sum of respective lengths of the m^{th} vertical data link line VLIAm and the m^{th} vertical power link line VLIAm_P can correspond to the sum of respective lengths of the j^{th} vertical data link line VLIAj and the j^{th} vertical power link line VLIAj_P.

Here, the corresponding of the sums of the lengths to each other can mean that the sums of the lengths are exactly the same or substantially the same within a tolerance.

Each of a plurality of data lines DL can be electrically connected to the data pad DP without using vertical data link lines VLIA and/or horizontal data link lines HLIA.

A plurality of data lines DL can be disposed based on the data link structure and the power line structure.

At least one of the plurality of data lines DL can be a bypass type data line DL, which is electrically connected to at least one data pad DP without being electrically connected with display area data link lines LIA. But aspects of the present disclosure are not limited thereto.

For example, at least one bypass type data line DL among the plurality of data lines DL can be disposed between two adjacent vertical data link lines (e.g., VLIA1 and VLIA2) among the plurality of vertical data link lines VLIA.

In another example, at least one bypass type data line DL among the plurality of data lines DL can be disposed between two adjacent vertical power distribution lines (e.g., V_PDW2 and V_PDW3) among a plurality of vertical power distribution lines V_PDW.

In another example, at least one bypass type data line DL among the plurality of data lines DL can be disposed between one vertical power distribution line (e.g., V_PDW1) among the plurality of vertical power distribution lines V_PDW and one vertical data link line (e.g., VLIA13) among the plurality of the vertical data link lines VLIA.

Each of the plurality of subpixels SP disposed in the display area AA can include a light emitting element ED including a pixel electrode PE and a common electrode CE.

A second common driving voltage (e.g., the second common driving voltage VSS of FIG. 2) can be applied to the common electrode CE, and the second common driving voltage VSS can be transferred to the common electrode CE by the power line structure.

Accordingly, the common electrode CE can be electrically connected to a plurality of vertical power distribution lines V_PDW, a plurality of horizontal power link lines HLIA_P, and a plurality of vertical power link lines VLIA_P.

A second common driving voltage line (e.g., the second common driving voltage line VSSL of FIG. 2) can be configured by at least one of the plurality of vertical power distribution lines V_PDW, the plurality of horizontal power link lines HLIA_P, and the plurality of vertical power link lines VLIA_P.

In one or more aspects, the display apparatus 100 and/or the display panel 110 included in the display apparatus 100 can include a substrate 111 (e.g., the substrate 111 of FIG. 2) including the display area AA including a plurality of subpixels SP and the non-display area NA located outside of the display area AA and including the pad area PA. In one or more aspects, the display apparatus 100 and/or the display panel 110 can include a plurality of data lines DL extending in the column direction in the display area AA, a plurality of data pads DP disposed in the pad area PA, a plurality of vertical data link lines VLIA electrically connected to the plurality of data pads DP and extending in the column direction in the display area AA, and a plurality of horizontal data link lines HLIA electrically connecting the plurality of vertical data link lines VLIA to the plurality of data lines DL and extending in the row direction in the display area AA. In one or more aspects, the display apparatus 100 and/or the display panel 110 can include at least one power pad PP disposed in the pad area PA, a power supply line PIW electrically connected to the at least one power pad PP and disposed in the non-display area NA, at least one power distribution line PDW electrically connected to the power supply line PIW, and a plurality of power link lines LIA_P disposed in the display area AA and electrically connected to the at least one power distribution line PDW.

Layers to which the data link structure and the power line structure are applied, or layers in which elements, such as lines and the like, related to the data link structure and the power line structure are disposed, can be related to each other.

In the data link structure, a plurality of horizontal data link lines HLIA can be disposed in a first metal layer (e.g., the first metal layer ML1 of FIGS. 9 and 10), and a plurality of vertical data link lines VLIA can be disposed in a second metal layer (e.g., the second metal layer ML2 of FIGS. 9 and 10).

In the power line structure, a plurality of vertical power distribution lines V_PDW can be disposed in the second metal layer ML2. A plurality of vertical power link lines VLIA_P can be disposed in the second metal layer ML2, and a plurality of horizontal power link lines HLIA_P can be disposed in the first metal layer ML1.

In the data link structure and the power line structure, horizontal lines extending in the row direction can be disposed in the first metal layer ML1, and vertical lines extending in the column direction can be disposed in the second metal layer ML2. But aspects of the present disclosure are not limited thereto.

For example, the horizontal lines can include a plurality of horizontal data link lines HLIA and a plurality of horizontal power link lines HLIA_P, and the vertical lines can include a plurality of vertical data link lines VLIA, a plurality of vertical power distribution lines V_PDW and a plurality of vertical power link lines VLIA_P.

The first metal layer ML1 can be a metal layer between a second interlayer insulating layer (e.g., the second interlayer insulating layer 323 of FIGS. 3, 9, and 10) and a first planarization layer (e.g., the first planarization layer 331 of FIGS. 3, 9, and 10), and can be a first source-drain metal layer. For example, referring to FIG. 3, the source electrodes E1b and E2b and the drain electrodes E1c and E2c of FIG. 3 can be disposed in the first metal layer ML1.

The second metal layer ML2 can be a metal layer between the first planarization layer 331 and a second planarization layer (e.g., the second planarization layer 332 of FIGS. 3, 9, and 10), and can be a second source-drain metal layer. For example, referring to FIG. 3, the connection electrode RE of FIG. 3 can be disposed in the second metal layer ML2.

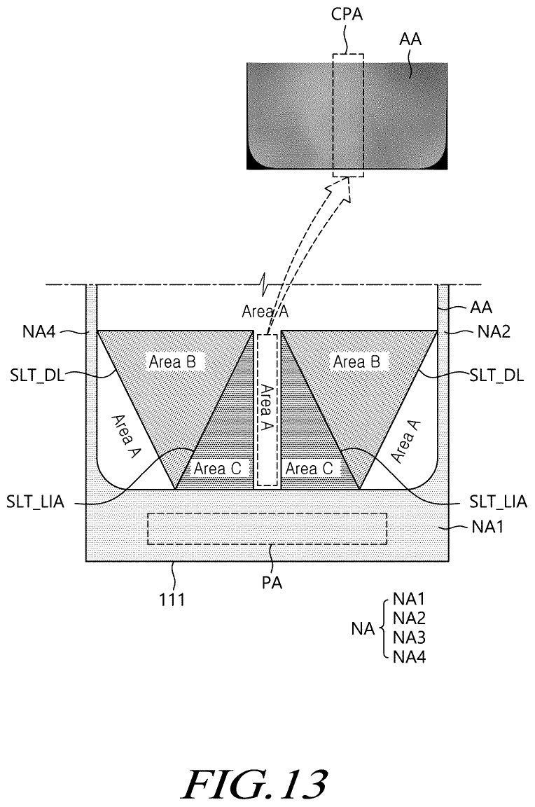

FIG. 13 illustrates some color artifacts (e.g., a defect where adjacent colors difference into each other) vertically recognized in a power area disposed in a central portion of the display panel 110 according to aspects of the present disclosure.

Referring to FIG. 13, an area between two third areas (Area C) (e.g., the two third areas (Area C) of FIGS. 7 and 11) can correspond to a portion of a first area (Area A) (e.g., the first area (Area A) of FIGS. 7 and 11), and can be a central power area CPA of the display area AA. A plurality of vertical power distribution lines V_PDW can be densely disposed in the central power area CPA.

Thus, metals disposed in subpixels SP in the central power area CPA can form unnecessary parasitic capacitance with at least one of the plurality of vertical power distribution lines V_PDW. However, subpixels SP disposed in an area different from the central power area CPA need not form unnecessary parasitic capacitance with the plurality of vertical power distribution lines V_PDW.

As such, the subpixels SP disposed in the central power area CPA and the subpixels SP disposed in the area different from the central power area CPA can have different capacitance components.

This can cause a luminance difference between the subpixels SP disposed in the central power area CPA and the subpixels SP disposed in the area different from the central power area CPA. For example, a difference in luminance between the central power area CPA and the area different from the central power area CPA can occur. This luminance difference can lead to color artifacts, for example, a defect where adjacent colors difference into each other, vertically recognized in the central power area CPA.

To address this issue, in one or more aspects, the display apparatus 100 and/or the display panel 110 can be configured with a power line structure capable of preventing color artifacts in the central power area CPA caused due to a luminance difference between the central power area CPA and an area different from the central power area CPA.

Hereinafter, such a power line structure capable of reducing a luminance difference between areas is described.

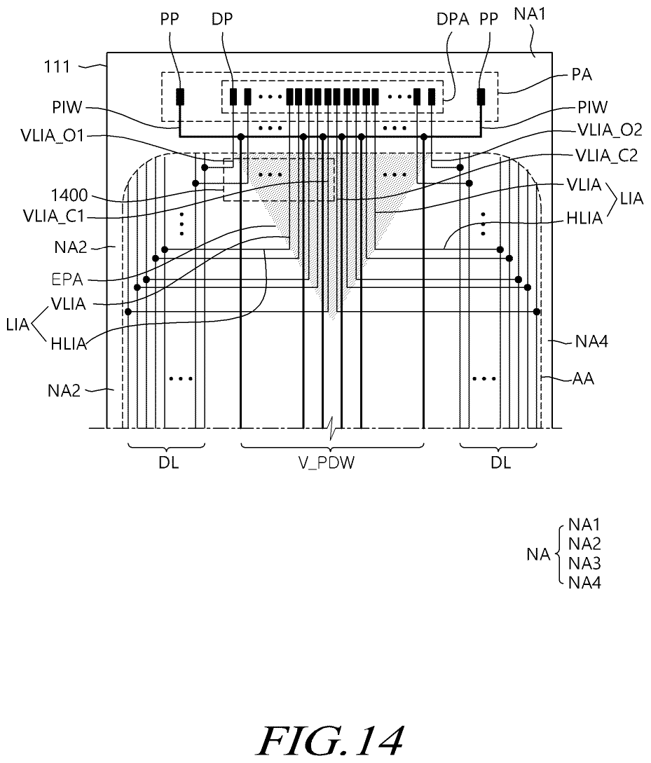

FIG. 14 is another plan view of the display panel 110 according to aspects of the present disclosure having a power line structure associated with the bezel reduction data link structure. For simplicity, discussions that follow are provided by focusing on structures or features different from those of FIG. 11. Thus, discussions on structures or features that are the same or substantially the same as those of FIG. 11 are omitted.

Referring to FIG. 14, the display area AA can include an expanded power area EPA resulting from combining the two third areas (Area C) and the central power area CPA.

FIG. 14 illustrates that a plurality of vertical power distribution lines V_PDW are not densely disposed in the central area, which is compared with the configuration of FIG. 11. Instead, the plurality of vertical power distribution lines V_PDW can be distributed from a left portion to a right portion of the expanded power area EPA.

By disposing the plurality of vertical power distribution lines V_PDW to be distributed across a wide area (e.g., the expanded power area EPA), parasitic capacitances caused by the plurality of vertical power distribution lines V_PDW, which affect subpixels SP, can be distributed evenly. Accordingly, image artifacts recognized in a narrow area (e.g., the central power area CPA in FIG. 13) can be prevented.

Referring to FIG. 14, in one or more aspects, in the left (or first) half area or right (or second) half area of the display area AA, at least one vertical power distribution line V_PDW can be disposed between two adjacent vertical data link lines VLIA among a plurality of vertical data link lines VLIA.

In the left half area or right half area of the display area AA, at least one data line DL or at least one vertical data link line VLIA can be disposed between two adjacent vertical power distribution lines V_PDW among a plurality of vertical power distribution lines V_PDW.

In one or more aspects, the plurality of vertical data link lines VLIA can include a first central vertical data link line VLIA_C1 and a second central vertical data link line VLIA_C2, which are disposed at a central portion of an area where the plurality of vertical data link lines VLIA are disposed, and a first outmost vertical data link line VLIA_O1 and a second outmost vertical data link line VLIA_O2, which are disposed at opposing outmost side portions of the area where the plurality of vertical data link lines VLIA are disposed.

The plurality of vertical power distribution lines V_PDW can include at least one first vertical power distribution line V_PDW and at least one second vertical power distribution line V_PDW. The at least one first vertical power distribution line V_PDW can be disposed between the first outmost vertical data link line VLIA_O1 and the first central vertical data link line VLIA_C1. The at least one second vertical power distribution line V_PDW can be disposed between the second outmost vertical data link line VLIA_O2 and the second central vertical data link line VLIA_C2.

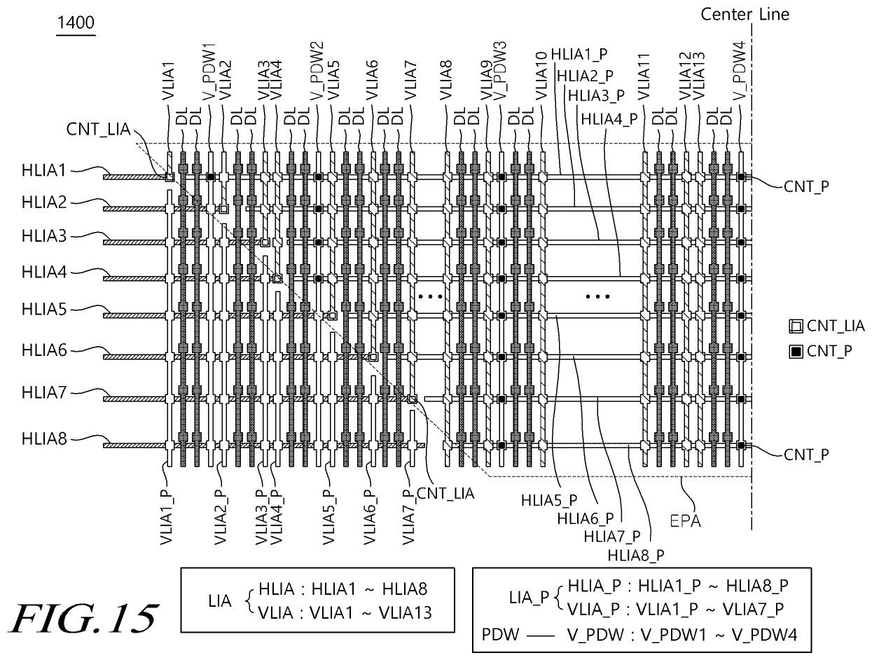

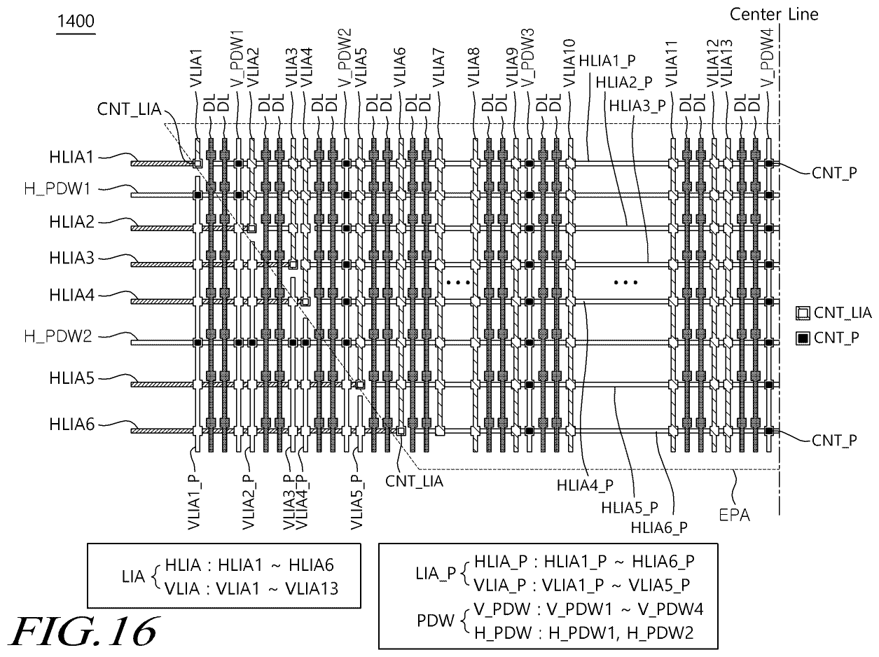

FIGS. 15 and 16 are plan views of a partial area 1400 in the configuration of FIG. 14.

Referring to FIGS. 15 and 16, in one or more aspects, a data link structure of the display panel 110 can include a plurality of display area data link lines LIA including a plurality of horizontal data link lines HLIA and a plurality of vertical data link lines VLIA. But aspects of the present disclosure are not limited thereto.

For example, referring to FIG. 15, the plurality of horizontal data link lines HLIA can include first to eighth horizontal data link lines (HLIA1 to HLIA8), and the plurality of vertical data link lines VLIA can include first to thirteenth vertical data link lines (VLIA1 to VLIA13). This example is merely for convenience of explanation, therefore, aspects of the present disclosure are not limited thereto.

For example, referring to FIG. 16, the plurality of horizontal data link lines HLIA can include first to sixth horizontal data link lines (HLIA1 to HLIA6), and the plurality of vertical data link lines VLIA can include first to thirteenth vertical data link lines (VLIA1 to VLIA13). This example is merely for convenience of explanation, therefore, aspects of the present disclosure are not limited thereto.

Referring to FIGS. 15 and 16, in one or more aspects, the power line structure of the display panel 110 can include at least one power distribution line PDW for distributing a common driving voltage to the display area AA.

The at least one power distribution line PDW can be electrically connected to at least one power supply line PIW and can include a plurality of vertical power distribution lines V_PDW extending in the column direction in the display area AA.

For example, the plurality of vertical power distribution lines V_PDW can include a first vertical power distribution line V_PDW1, a second vertical power distribution line V_PDW2, a third vertical power distribution line V_PDW3, and a fourth power distribution line V_PDW4. This example is merely for convenience of explanation, therefore, aspects of the present disclosure are not limited thereto.

Referring to FIGS. 15 and 16, in one or more aspects, the first vertical power distribution line V_PDW1, the second vertical power distribution line V_PDW2, the third vertical power distribution line V_PDW3, and the fourth power distribution line V_PDW4 can be not densely disposed in the central area, which is compared with the configuration of FIG. 11. Instead, the first vertical power distribution line V_PDW1, the second vertical power distribution line V_PDW2, the third vertical power distribution line V_PDW3, and the fourth power distribution line V_PDW4 can be distributed or disposed from a left (or first) portion to a right (or second) portion of the display area AA.

In one or more aspects, in the left half area or right half area of the display area AA, at least one vertical power distribution line V_PDW can be disposed between two adjacent vertical data link lines VLIA among the plurality of vertical data link lines VLIA.

For example, the first vertical power distribution line V_PDW1 can be disposed between the first vertical data link line VLIA1 and the second vertical data link line VLIA2. The second vertical power distribution line V_PDW2 can be disposed between the fourth vertical data link line VLIA4 and the fifth vertical data link line VLIA5. The third vertical power distribution line V_PDW3 can be disposed between the ninth vertical data link line VLIA9 and the tenth vertical data link line VLIA10. The fourth vertical power distribution line V_PDW4 can be disposed between the thirteenth vertical data link line VLIA13 and a center line, which is a boundary between the left half area and right half area. In various aspects of the present disclosure, the vertical power distribution lines V_PDW can be interleaved within the data lines DL.

In various aspects of the present disclosure, portions of the at least one vertical power distribution line V_PDW can be located outside of the expanded power area EPA. For example, among the vertical power distribution lines, the first vertical power distribution wire V_PDW1 includes a first portion located inside or within the expanded power area EPA and a second portion located outside the expanded power area EPA. Similarly, the second vertical power distribution wire V_PDW2 includes a first portion located inside or within the expanded power area EPA and a second portion located outside the expanded power area EPA, but aspects of the present disclosure not limited thereto, and portions of the vertical power distribution line V_PDW can be located entirely inside of the expanded power area EPA as shown by the third vertical power distribution wire V_PDW3 and the fourth vertical power distribution wire V_PDW4.

In various aspects of the present disclosure, when a first portion of the vertical power distribution line V_PDW located inside or within the expanded power area EPA and a second portion of the vertical power distribution wire V_PDW located outside the expanded power area EPA can have the same length or different lengths. When different, the first portion can be longer or shorter than the second portion.

In various aspects of the present disclosure, a first portion of one vertical power distribution line V_PDW located inside or within the expanded power area EPA and a first portion of the vertical power distribution wire V_PDW located inside or within the expanded power area EPA can be the same or different lengths. Similarly, a second portion of one vertical power distribution line V_PDW located outside the expanded power area EPA and a second portion of the vertical power distribution wire V_PDW located outside the expanded power area EPA can be the same or different lengths. For example, the first portion of first vertical power distribution line V_PDW1 located inside or within the expanded power area EPA can be shorter than the first portion of the second vertical power distribution wire V_PDW2 located inside or within the expanded power area EPA.

When the first portion of the vertical power distribution line V_PDW is located inside or within the expanded power area EPA, a horizontal power link lines HLIA_P can be electrically connected to the vertical power distribution lines V_PDW through a power line connection hole CNT_P, but when the second portion of the vertical power distribution wire V_PDW is located outside the expanded power area EPA, the power line connection hole CNT_P need not be present.

In various aspects of the present disclosure, one or more of the vertical power distribution lines V_PDW can intersect the slant lines SLT_DL where data lines DL and horizontal data link lines HLIA are connected (see FIG. 6).

Referring to FIGS. 15 and 16, in one or more aspects, in the left half area or right half area of the display area AA, at least one data line DL or at least one vertical data link line VLIA can be disposed between two adjacent vertical power distribution lines V_PDW among the plurality of vertical power distribution lines V_PDW.

For example, K1 number of data lines DL and K2 number of vertical data link lines VLIA can be disposed between the second vertical power distribution line V_PDW2 and the third vertical power distribution wire V_PDW3.

In another example, three vertical data link lines (VLIA2, VLIA3, and VLIA4) and four data lines DL can be disposed between the first vertical power distribution line V_PDW1 and the second vertical power distribution line V_PDW2.

Referring to FIGS. 15 and 16, in one or more aspects, K number of vertical lines to which data signals are applied can be disposed between two adjacent vertical power distribution lines (e.g., V_PDW2 and V_PDW3) among the plurality of vertical power distribution lines V_PDW, where K can be a natural number of 2 or more.

The K number of vertical lines can be signal lines configured to transfer data signals and can include at least one vertical data link line VLIA and at least one data line DL.

Here, K, which is the number of vertical lines between two vertical power distribution lines (e.g., V_PDW2 and V_PDW3), can correspond to the number of subpixel columns and can be a value defined or determined according to the resolution of the display apparatus 100.

For example, K, which is the number of vertical lines between two vertical power distribution lines (e.g., V_PDW2 and V_PDW3), can be positively proportional to the resolution of the display apparatus 100 and can be inversely proportional to the number of vertical power distribution lines V_PDW. Here, the resolution of the display apparatus 100 can be positively proportional to the number of subpixel columns.

These configuration schemes can be applied between any two vertical power distribution lines, but can be not applied between two outmost vertical power distribution lines located in opposing outmost portions of the display area AA, or between two central vertical power distribution lines disposed in a central portion of the display area AA. Aspects of the present disclosure are not limited to such structures.

The total number of the plurality of vertical power distribution lines V_PDW can be determined depending on the total number of vertical lines (data lines DL and/or vertical data link lines VLIA) to which data signals are applied. At least one vertical line (at least one data line DL and/or at least one vertical data link line VLIA) to which a data signal is applied can be disposed between the plurality of vertical power distribution lines V_PDW.

For example, in the display apparatus 100, when the number of the plurality of data lines DL is N1, the number of the plurality of vertical data link lines VLIA is N2, and the number of the plurality of vertical power distribution lines V_PDW are N3, K, which is the number of vertical lines between two vertical power distribution lines (e.g., V_PDW2 and V_PDW3), can be proportional to (N1+N2)/(N3+C). Here, C is a constant, and for example, C can be 1. For example, K can be equal to (N1+N2)/(N3+1).

The sum of the total number (N1) of data lines DL to which data signals are applied and the total number (N2) of vertical data link lines VLIA to which data signals are applied can correspond to the total number of the subpixel columns in the display panel 110 and can vary depending on the resolution of the display panel 110.

Referring to FIG. 16, in one or more aspects, a power line structure of the display apparatus 100 can further include at least one horizontal power distribution line H_PDW. The at least one horizontal power distribution line H_PDW can be electrically connected to at least one of the plurality of vertical power distribution lines V_PDW and can extend in the row direction in the display area AA. For example, the horizontal power distribution line H_PDW can be a second power distribution line or a second power line, but aspects of the present disclosure are not limited thereto.

For example, the at least one horizontal power distribution line H_PDW can include a first horizontal power distribution line H_PDW1 and a second horizontal power distribution line H_PDW2. This example is merely for convenience of explanation; therefore, aspects of the present disclosure are not limited thereto. For example, the first horizontal power distribution line H_PDW1 can be a 2-1^{st} power distribution line or a second power distribution line, but aspects of the present disclosure are not limited thereto. For example, the second horizontal power distribution line H_PDW2 can be a 2-2^{nd} power distribution line or a third power distribution line, but aspects of the present disclosure are not limited thereto.

As the at least one horizontal power distribution line H_PDW is disposed, the resistance of transfer paths of a common driving voltage can be reduced and the transfer characteristics (transfer performance) of the common driving voltage can be improved.

Referring to FIG. 16, one horizontal power distribution line H_PDW can be disposed between two adjacent horizontal data link lines HLIA among the plurality of horizontal data link lines HLIA.

For example, the first horizontal power distribution line H_PDW1 can be disposed between the first horizontal data link line HLIA1 and the second horizontal data link line HLIA2. The second horizontal power distribution line H_PDW2 can be disposed between the fourth horizontal data link line HLIA4 and the fifth horizontal data link line HLIA5.

In various aspects of the present disclosure, when one or more of the horizontal power distribution lines H_PDW are provided, the one or more of the horizontal power distribution lines H_PDW can have a first portion located inside of the expanded power area EPA and a second portion located outside of the expanded power area EPA. In this instance, a first portion of a vertical power distribution line V_PDW located inside the expanded power area EPA and a second portion of the vertical power distribution line V_PDW located outside the expanded power area EPA can be respectively connected to a first portion of the horizontal power distribution line H_PDW located inside of the expanded power area EPA and a second portion of the horizontal power distribution line H_PDW located outside of the expanded power area EPA. The connection can be via one or more power line connection holes CNT_P.

In various aspects of the present disclosure, the first portion of the horizontal power distribution line H_PDW located inside or within the expanded power area EPA and a second portion of the horizontal power distribution wire H_PDW located outside the expanded power area EPA can have the same length or different lengths. When different, the first portion can be longer or shorter than the second portion.

The aspects described above will be briefly described as follows.

A display apparatus according to aspects of the present disclosure can include a substrate including a display area having a plurality of subpixels and a non-display area adjacent to the display area.

In one or more aspects, the display apparatus can include a plurality of data lines extending in a first direction in the display area, a plurality of vertical data link lines extending in the first direction in the display area, and a plurality of horizontal data link lines extending in a second direction in the display area.

In one or more aspects, the display apparatus can include a power supply line disposed in the non-display area, a plurality of vertical power distribution lines electrically connected to the power supply line and extending in the first direction in the display area, a plurality of horizontal power link lines extending in the second direction in the display area, and a plurality of vertical power link lines extending in the first direction in the display area.

In one or more aspects, the plurality of vertical data link lines can include a first central vertical data link line and a second central vertical data link line disposed at a center area among the plurality of vertical data link lines, and a first outmost vertical data link line and a second outmost vertical data link line disposed at both sides among the plurality of vertical data link lines.

In one or more aspects, a length of the first central vertical data link line can be longer than a length of the first outmost vertical data link line. A length of the second central vertical data link line can be longer than a length of the second outmost vertical data link line.

In one or more aspects, a length of a horizontal data link line connected to the first central vertical data link line can be longer than a length of a horizontal data link line connected to the first outmost vertical data link line.

In one or more aspects, a length of a horizontal data link line connected to the second central vertical data link line can be longer than a length of a horizontal data link line connected to the second outmost vertical data link line.

In one or more aspects, the plurality of horizontal data link lines can include a first horizontal data link line and a second horizontal data link line disposed further away from a pad area than the first horizontal data link line.

In one or more aspects, a length of the second horizontal data link line can be greater than a length of the first horizontal data link line.

In one or more aspects, the plurality of horizontal power link lines can include a first horizontal power link line disposed in the same first row as the first horizontal data link line and spaced apart from the first horizontal data link line, and a second horizontal power link line disposed in the same second row as the second horizontal data link line and spaced apart from the second horizontal data link line.

In one or more aspects, a length of the second horizontal power link line can be shorter than a length of the first horizontal power link line.

In one or more aspects, the plurality of horizontal data link lines can be disposed in a first metal layer. The plurality of vertical data link lines can be disposed in a second metal layer different from the first metal layer.

In one or more aspects, the first metal layer and the second metal layer can be on different planes.

In one or more aspects, the plurality of vertical power distribution lines can be disposed in the second metal layer. The plurality of vertical power link lines can be disposed in the second metal layer.

In one or more aspects, the plurality of horizontal power link lines can be disposed in the first metal layer.

In one or more aspects, an n^{th} horizontal data link line among the plurality of horizontal data link lines and an n^{th} horizontal power link line among the plurality of horizontal power link lines can correspond to each other. Here, n may be a natural number equal to or greater than 1. The n^{th} horizontal data link line and the n^{th} horizontal power link line can be disposed to be spaced apart from each other in a same n^{th} row.

In one or more aspects, an m^{th} vertical data link line among the plurality of vertical data link lines and an m^{th} vertical power link line among the plurality of vertical power link lines can correspond to each other. Here, m may be a natural number equal to or greater than 1. The m^{th} vertical data link line and the m^{th} vertical power link line can be disposed to be spaced apart from each other in a same m^{th} column.

In one or more aspects, an i^{th} horizontal data link line among the plurality of horizontal data link lines and an i^{th} horizontal power link line among the plurality of horizontal power link lines can correspond to each other. Here, i can be a natural number equal to or greater than 1. The i^{th} horizontal data link line and the i^{th} horizontal power link line can be disposed to be spaced apart from each other in the same i^{th} row.

In one or more aspects, a j^{th} vertical data link line among the plurality of vertical data link lines and a j^{th} vertical power link line among the plurality of vertical power link lines can correspond to each other. Here, j can be a natural number equal to or greater than 1. The j^{th} vertical data link line and the j^{th} vertical power link line can be disposed to be spaced apart from each other in the same j^{th} column.

In one or more aspects, a sum of respective lengths of the n^{th} horizontal data link line and the n^{th} horizontal power link line can correspond to a sum of respective lengths of the i^{th} horizontal data link line and the i^{th} horizontal power link line.

In one or more aspects, a sum of respective lengths of the m^{th} vertical data link line and the m^{th} vertical power link line can correspond to a sum of respective lengths of the j^{th} vertical data link line and the j^{th} vertical power link line.

In one or more aspects, at least one of the plurality of data lines can be disposed between two adjacent vertical data link lines among the plurality of vertical data link lines, or can be disposed between two adjacent vertical power distribution lines among the plurality of vertical power distribution lines, or can be disposed between one vertical power distribution line of the plurality of vertical power distribution lines and one vertical data link line of the plurality of vertical data link lines. At least one of the plurality of data lines can include, for example, a bypass type data line that is electrically connected to a data pad without using a data link wiring structure of the display area.

In one or more aspects, each of the plurality of vertical power link lines can have a length longer than the longest vertical data link line among the plurality of vertical data link lines.

In one or more aspects, the plurality of vertical data link lines can include a first central vertical data link line and a second central vertical data link line disposed at a center among the plurality of vertical data link lines.

In one or more aspects, the plurality of vertical power distribution lines can be disposed between the first central vertical data link line and the second central vertical data link line.

In one or more aspects, the display area can include a first area in which the plurality of horizontal data link lines and the plurality of vertical data link lines are not disposed, two second areas in which the plurality of horizontal data link lines are disposed, and two third areas in which the plurality of vertical data link lines are disposed.

In one or more aspects, an area between the two third areas can correspond to a portion of the first area.

In one or more aspects, the plurality of vertical power distribution lines can be disposed in a central power area being an area between the two third areas.

In one or more aspects, in a first half area or a second half area of the display area, at least one vertical power distribution line can be disposed between two adjacent vertical data link lines among the plurality of vertical data link lines.

In one or more aspects, in a first half area or a second half area of the display area, at least one data line or at least one vertical data link line can be disposed between two adjacent vertical power distribution lines among the plurality of vertical power distribution lines.

In one or more aspects, a K number of vertical lines to which data signals are applied can be disposed between two adjacent vertical power distribution lines among the plurality of vertical power distribution lines, where K can be a natural number equal to or greater than 2.

In one or more aspects, the K number of vertical lines can include at least one vertical data link line and at least one data line. Here, K can be positively proportional to the resolution of the display apparatus and inversely proportional to the number of the vertical power distribution lines.

In one or more aspects, the number of the plurality of data lines can be N1, the number of the plurality of vertical data link lines can be N2, the number of the plurality of vertical power distribution lines can be N3, and K can be positively proportional to (N1+N2)/(N3+1).

In one or more aspects, the display apparatus can further include at least one horizontal power distribution line electrically connected to the at least one of the plurality of vertical power distribution lines and extending in the second direction in the display area.

In one or more aspects, one of the at least one horizontal power distribution line can be disposed between two adjacent horizontal data link lines among the plurality of horizontal data link lines.

In one or more aspects, each of the plurality of subpixels can include a light emitting element including a pixel electrode and a common electrode. The common electrode can be electrically connected to the plurality of vertical power distribution lines, the plurality of horizontal power link lines, and the plurality of vertical power link lines.

In one or more aspects, the non-display area can include a pad area including a plurality of data pads and at least one power pad. The plurality of vertical data link lines can be electrically connected to the plurality of data pads. The power supply line can be electrically connected to the at least one power pad.

In one or more aspects, the plurality of horizontal data link lines can electrically connect the plurality of vertical data link lines to the plurality of data lines. The plurality of vertical power distribution lines can be electrically connected to the power supply line. The plurality of horizontal power link lines and the plurality of vertical power link lines can be electrically connected to the plurality of vertical power distribution lines.

In one or more aspects, the plurality of vertical power distribution lines can include at least one first vertical power distribution line and at least one second vertical power distribution line.

In one or more aspects, the at least one first vertical power distribution line can be disposed between the first outmost vertical data link line and the first central vertical data link line.

In one or more aspects, the at least one second vertical power distribution line can be disposed between the second outmost vertical data link line and the second central vertical data link line.

In one or more aspects, the second area can have an inverted triangle shape or an isosceles triangle shape, and the third area has a right triangle shape.

In one or more aspects, a boundary between the first area and each of the two second areas can correspond to portions where the horizontal data link lines and the data lines are connected, and form a first slant line.

In one or more aspects, a boundary between a corresponding second area and a corresponding third area can correspond to portions where the vertical data link lines and the horizontal data link lines are connected, and form a second slant line.

In one or more aspects, the display area can include an expanded power area resulting from combining the two third areas and a central power area being an area between the two third areas.

In one or more aspects, the plurality of vertical power distribution lines can be distributed from a first portion to a second portion of the expanded power area.

In one or more aspects, the display apparatus can further comprise at least one horizontal metal layer and at least one vertical metal layer. The horizontal metal layer can be spaced apart from the horizontal data link line, extend in the row direction, and can be disposed in the first metal layer. The vertical metal layer can be spaced apart from the vertical data link line, extend in the column direction, and is disposed in the second metal layer

In one or more aspects, the horizontal metal layer and the vertical metal layer can be configured in a mesh pattern.

In one or more aspects, each of the plurality of vertical power distribution lines can have a length longer than each of the plurality of vertical data link lines.

In one or more aspects, the display apparatus can include a substrate including a display area having a plurality of subpixels and a non-display area adjacent to the display area.

In one or more aspects, the display apparatus can include a plurality of data lines extending in a first direction in the display area, a plurality of vertical data link lines extending in the first direction in the display area, and a plurality of horizontal data link lines extending in a second direction in the display area.

In one or more aspects, the display apparatus can include a power supply line disposed in the non-display area, at least one power distribution line, and a plurality of power link lines disposed in the display area and electrically connected to the at least one power distribution line.

In one or more aspects, the plurality of power link lines can include a plurality of first power link lines extending in the second direction and a plurality of second power link lines extending in the first direction.

In one or more aspects, the non-display area can include a pad area including a plurality of data pads and at least one power pad. The plurality of vertical data link lines can be electrically connected to the plurality of data pads. The power supply line can be electrically connected to the at least one power pad.

In one or more aspects, the display apparatus can further include a plurality of data lines extending in the first direction in the display area. The plurality of horizontal data link lines can electrically connect the plurality of vertical data link lines to the plurality of data lines.

In one or more aspects, the at least one power distribution line can be electrically connected to the power supply line.

In one or more aspects, the display area can include a first area in which the vertical data link lines and the horizontal data link lines are not disposed, two second areas in which the plurality of horizontal data link lines are disposed, and two third areas in which the plurality of vertical data link lines are disposed. In one or more aspects, an area between the two third areas can correspond to a portion of the first area.

In one or more aspects, the at least one power distribution line can be disposed in a central power area being an area between the two third areas.

In one or more aspects, the display area can include an expanded power area resulting from combining the two third areas and a central power area being an area between the two third areas.

In one or more aspects, the at least one power distribution line can be distributed from a first portion to a second portion of the expanded power area.

In one or more aspects, the second area can have an inverted triangle shape or an isosceles triangle shape, and the third area can have a right triangle shape.

A display apparatus according to aspects of the present disclosure can include a substrate including a display area having a plurality of subpixels and a non-display area adjacent to the display area. The display apparatus can include a plurality of vertical data link lines extending in a first direction in the display area, a plurality of horizontal data link lines extending in a second direction in the display area, a plurality of power link lines disposed in a power area of the display area, and at least one vertical power distribution line.

In one or more aspects, the plurality of horizontal data link lines can be not located in the power area.

In one or more aspects, the at least one vertical power distribution line can extend from the power area to an area of the display area that is outside the power area.

In one or more aspects, the display apparatus can further include at least one horizontal power distribution line electrically connected to the at least one vertical power distribution line, and located in the area of the display area that is outside the power area.

According to aspects of the present disclosure, a display apparatus can be provided that has a bezel reduction data link structure.

According to aspects of the present disclosure, a display apparatus can be provided that has a power line structure capable of improving the performance of transmitting a common driving voltage.

According to aspects of the present disclosure, a display apparatus can be provided that has a power line structure capable of helping to improve image quality.

According to aspects of the present disclosure, a display apparatus can be provided that has a power line structure suitable for a bezel reduction data link structure.

According to aspects of the present disclosure, a display apparatus and a display panel can be provided that are capable of reducing the bezel of the display panel by applying an improved data link structure, and are configured to have a reduced weight.

A display apparatus according to the aspects of the present disclosure can be applied to mobile devices, video phones, smart watches, watch phones, wearable apparatuses, foldable apparatuses, rollable apparatuses, bendable apparatuses, flexible apparatuses, stretchable apparatuses, curved apparatuses, sliding apparatuses, variable apparatuses, electronic notebooks, e-books, portable multimedia players (PMP), personal digital assistants (PDA), MP3 players, mobile medical apparatuses, desktop PCs, laptop PCs, netbook computers, workstations, navigation apparatuses, car navigation apparatuses, vehicle display apparatuses, vehicle apparatuses, theater apparatuses, theater display apparatuses, televisions, wallpaper apparatuses, signage apparatuses, game apparatuses, notebook computers, monitors, cameras, camcorders, and home appliances, and the like.

It will be apparent to those skilled in the art that various modifications and variations can be made in the present disclosure without departing from the scope of the disclosures. Thus, it is intended that the present disclosure covers the modifications and variations of this disclosure that come within the scope of the appended claims and their equivalents.

What is claimed is:

1. A display apparatus, comprising:
a substrate comprising a display area having a plurality of subpixels and a non-display area adjacent to the display area;
a plurality of data lines extending in a first direction in the display area;
a plurality of vertical data link lines extending in the first direction in the display area;
a plurality of horizontal data link lines extending in a second direction in the display area;
a power supply line disposed in the non-display area;
a plurality of vertical power distribution lines electrically connected to the power supply line and extending in the first direction in the display area;
a plurality of horizontal power link lines extending in the second direction in the display area; and
a plurality of vertical power link lines extending in the first direction in the display area.

2. The display apparatus of claim 1, wherein the plurality of vertical data link lines comprise:
a first central vertical data link line and a second central vertical data link line disposed at a center area among the plurality of vertical data link lines; and
a first outmost vertical data link line and a second outmost vertical data link line, which are both outmost vertical data link lines among the plurality of vertical data link lines, and
wherein a length of the first central vertical data link line is longer than a length of the first outmost vertical data link line, and a length of the second central vertical data link line is longer than a length of the second outmost vertical data link line.

3. The display apparatus of claim 1, wherein the plurality of vertical data link lines comprise:
a first central vertical data link line and a second central vertical data link line disposed at a center area among the plurality of vertical data link lines; and
a first outmost vertical data link line and a second outmost vertical data link line, which are both outmost vertical data link lines among the plurality of vertical data link lines,
wherein a length of a horizontal data link line connected to the first central vertical data link line is longer than a length of a horizontal data link line connected to the first outmost vertical data link line, and
wherein a length of a horizontal data link line connected to the second central vertical data link line is longer than a length of a horizontal data link line connected to the second outmost vertical data link line.

4. The display apparatus of claim 1, wherein the plurality of horizontal data link lines comprise:
a first horizontal data link line; and
a second horizontal data link line disposed further away from a pad area than the first horizontal data link line, and
wherein a length of the second horizontal data link line is longer than a length of the first horizontal data link line.

5. The display apparatus of claim 4, wherein the plurality of horizontal power link lines comprise:
a first horizontal power link line disposed in a same first row as the first horizontal data link line and spaced apart from the first horizontal data link line; and
a second horizontal power link line disposed in a same second row as the second horizontal data link line and spaced apart from the second horizontal data link line, and
wherein a length of the second horizontal power link line is shorter than a length of the first horizontal power link line.

6. The display apparatus of claim 1, wherein the plurality of horizontal data link lines are disposed in a first metal layer, and the plurality of vertical data link lines are disposed in a second metal layer different from the first metal layer, and
wherein the first metal layer and the second metal layer are on different planes.

7. The display apparatus of claim 6, wherein the plurality of vertical power distribution lines are disposed in the second metal layer, the plurality of vertical power link lines are disposed in the second metal layer, and the plurality of horizontal power link lines are disposed in the first metal layer.

8. The display apparatus of claim 1, wherein an n^{th} horizontal data link line among the plurality of horizontal data link lines and an n^{th} horizontal power link line among the plurality of horizontal power link lines correspond to each other, where n is a natural number equal to or greater than 1, and
wherein the n^{th} horizontal data link line and the n^{th} horizontal power link line are disposed to be spaced apart from each other in a same n^{th} row.

9. The display apparatus of claim 8, wherein an i^{th} horizontal data link line among the plurality of horizontal data link lines and an i^{th} horizontal power link line among the plurality of horizontal power link lines correspond to each other, where i is a natural number equal to or greater than 1,
wherein the i^{th} horizontal data link line and the i^{th} horizontal power link line are disposed to be spaced apart from each other in a same i^{th} row, and
wherein a sum of respective lengths of the n^{th} horizontal data link line and the n^{th} horizontal power link line corresponds to a sum of respective lengths of the i^{th} horizontal data link line and the i^{th} horizontal power link line.

10. The display apparatus of claim 1, wherein an m^{th} vertical data link line among the plurality of vertical data link lines and an m^{th} vertical power link line among the plurality of vertical power link lines correspond to each other, where m is a natural number equal to or greater than 1, and
wherein the m^{th} vertical data link line and the m^{th} vertical power link line are disposed to be spaced apart from each other in a same m^{th} column.

11. The display apparatus of claim 10, wherein a j^{th} vertical data link line among the plurality of vertical data link lines and a j^{th} vertical power link line among the plurality of vertical power link lines correspond to each other, where j is a natural number equal to or greater than 1,
wherein the j^{th} vertical data link line and the j^{th} vertical power link line are disposed to be spaced apart from each other in a same j^{th} column, and
wherein a sum of respective lengths of the m^{th} vertical data link line and the m^{th} vertical power link line corresponds to a sum of respective lengths of the j^{th} vertical data link line and the j^{th} vertical power link line.

12. The display apparatus of claim 1, wherein at least one of the plurality of data lines is disposed between two adjacent vertical data link lines among the plurality of vertical data link lines, or
wherein at least one of the plurality of data lines is disposed between two adjacent vertical power distribution lines among the plurality of vertical power distribution lines, or
wherein at least one of the plurality of data lines is disposed between one vertical power distribution line of the plurality of vertical power distribution lines and one vertical data link line of the plurality of vertical data link lines.

13. The display apparatus of claim 1, wherein each of the plurality of vertical power link lines has a length longer than a longest vertical data link line among the plurality of vertical data link lines.

14. The display apparatus of claim 1, wherein the plurality of vertical data link lines comprise a first central vertical data link line and a second central vertical data link line disposed at a center area among the plurality of vertical data link lines, and
wherein the plurality of vertical power distribution lines are disposed between the first central vertical data link line and the second central vertical data link line.

15. The display apparatus of claim 1, wherein the display area comprises:
a first area in which the plurality of horizontal data link lines and the plurality of vertical data link lines are not disposed;
two second areas in which the plurality of horizontal data link lines are disposed; and
two third areas in which the plurality of vertical data link lines are disposed, and
wherein an area between the two third areas corresponds to a portion of the first area.

16. The display apparatus of claim 15, wherein the plurality of vertical power distribution lines are disposed in a central power area being an area between the two third areas.

17. The display apparatus of claim 1, wherein in a first half area or a second half area of the display area, at least one vertical power distribution line is disposed between two adjacent vertical data link lines among the plurality of vertical data link lines.

18. The display apparatus of claim 1, wherein in a first half area or a second half area of the display area, at least one data line or at least one vertical data link line is disposed between two adjacent vertical power distribution lines among the plurality of vertical power distribution lines.

19. The display apparatus of claim 1, wherein a K number of vertical lines to which data signals are applied are disposed between two adjacent vertical power distribution lines among the plurality of vertical power distribution lines, where K is a natural number equal to or greater than 2,
wherein the K number of vertical lines comprise at least one vertical data link and at least one data line, and
wherein K is positively proportional to resolution of the display apparatus and inversely proportional to a number of the vertical power distribution lines.

20. The display apparatus of claim 19, wherein a number of the plurality of data lines is N1, a number of the plurality of vertical data link lines is N2, a number of the plurality of vertical power distribution lines is N3, and K is positively proportional to (N1+N2)/(N3+1).

21. The display apparatus of claim 1, further comprising at least one horizontal power distribution line electrically connected to the at least one of the plurality of vertical power distribution lines and extending in the second direction in the display area.

22. The display apparatus of claim 21, wherein one of the at least one horizontal power distribution line is disposed between two adjacent horizontal data link lines among the plurality of horizontal data link lines.

23. The display apparatus of claim 1, wherein each of the plurality of subpixels comprises a light emitting element including a pixel electrode and a common electrode, and
wherein the common electrode is electrically connected to the plurality of vertical power distribution lines, the plurality of horizontal power link lines, and the plurality of vertical power link lines.

24. The display apparatus of claim 1, wherein the non-display area comprises a pad area including a plurality of data pads and at least one power pad,
wherein the plurality of vertical data link lines are electrically connected to the plurality of data pads, and
wherein the power supply line is electrically connected to the at least one power pad.

25. The display apparatus of claim 1, wherein the plurality of horizontal data link lines electrically connect the plurality of vertical data link lines to the plurality of data lines,
wherein the plurality of vertical power distribution lines are electrically connected to the power supply line, and
wherein the plurality of horizontal power link lines and the plurality of vertical power link lines are electrically connected to the plurality of vertical power distribution lines.

26. A display apparatus, comprising:
a substrate including a display area having a plurality of subpixels and a non-display area adjacent to the display area;
a plurality of vertical data link lines extending in a first direction in the display area;
a plurality of horizontal data link lines extending in a second direction in the display area;
a power supply line disposed in the non-display area;
at least one power distribution line; and
a plurality of power link lines disposed in the display area and electrically connected to the at least one power distribution line.

27. The display apparatus of claim 26, wherein the plurality of power link lines comprise:
a plurality of first power link lines extending in the second direction; and
a plurality of second power link lines extending in the first direction.

28. The display apparatus of claim 26, wherein the non-display area comprises a pad area including a plurality of data pads and at least one power pad,
wherein the plurality of vertical data link lines are electrically connected to the plurality of data pads, and
wherein the power supply line is electrically connected to the at least one power pad.

29. The display apparatus of claim 26, wherein the at least one power distribution line is electrically connected to the power supply line.

30. The display apparatus of claim 26, wherein the display area comprises:
a first area in which the plurality of horizontal data link lines and the plurality of vertical data link lines are not disposed;
two second areas in which the plurality of horizontal data link lines are disposed; and
two third areas in which the plurality of vertical data link lines are disposed, and
wherein an area between the two third areas corresponds to a portion of the first area.

31. The display apparatus of claim 30, wherein the at least one power distribution line is disposed in a central power area being an area between the two third areas.
